(19) United States
(12) Patent Application Publication
(10) Pub. No.: US 2022/0399418 A1
(43) Pub. Date: Dec. 15, 2022

(54) DISPLAY PANEL AND DISPLAY APPARATUS

(71) Applicant: Samsung Display Co., Ltd., Yongin-si (KR)

(72) Inventors: Seunglyong Bok, Yongin-si (KR); Dongho Lee, Yongin-si (KR); Okkyung Park, Yongin-si (KR)

(21) Appl. No.: 17/518,618

(22) Filed: Nov. 4, 2021

(30) Foreign Application Priority Data
Jun. 14, 2021 (KR) 10-2021-0076994

(51) Int. Cl. H01L 27/32; G06F 1/16

(52) U.S. Cl. CPC H01L 27/3262; H01L 27/3276; H01L 27/3218; G06F 1/1616

(57) ABSTRACT

Disclosed is a display panel including: a substrate; a pixel circuit layer including a first pixel circuit which includes a plurality of first thin-film transistors and a second pixel circuit which includes a plurality of second thin-film transistors; and a display element layer including a first display element connected to the first pixel circuit and a second display element connected to the second pixel circuit. The number of the plurality of first thin-film transistors in the first pixel circuit is greater than the number of the plurality of second thin-film transistors in the second pixel circuit, and the display panel has a first surface including a first display area and has a second surface opposite to the first surface and including a second display area.

### CROSS-REFERENCE TO RELATED APPLICATION

This application is based on and claims priority under 35 U.S.C. § 119 to Korean Patent Application No. 10-2021-0076994, filed on Jun. 14, 2021, in the Korean Intellectual Property Office, the disclosure of which is incorporated herein in its entirety by reference.

### BACKGROUND

### 1. Field

One or more embodiments relate to a display panel and a display apparatus.

### 2. Description of the Related Art

Applications of display apparatuses have recently diversified. In addition, display apparatuses have become thinner and lighter, and thus their range of applications has widened.

As display apparatuses are utilized in various ways, there may be various methods of designing the shapes of display apparatuses. The area occupied by a display area of display apparatuses has been increased, and also various functions that may be applied or linked to display apparatuses have been added to display apparatuses.

### SUMMARY

One or more embodiments include a display panel and a display apparatus for displaying an image on both surfaces.

One or more embodiments include a display apparatus capable of performing a component operation or displaying an image when the display apparatus is folded about a folding axis.

Additional aspects will be set forth in part in the description which follows and, in part, will be apparent from the description, or may be learned by practice of the presented embodiments of the disclosure.

According to one or more embodiments, a display panel includes a substrate, a pixel circuit layer disposed on the substrate and including a first pixel circuit which includes a plurality of first thin-film transistors and a second pixel circuit which includes a plurality of second thin-film transistors, and a display element layer disposed on the pixel circuit layer and including a first display element connected to the first pixel circuit and a second display element connected to the second pixel circuit. A number of the plurality of first thin-film transistors in the first pixel circuit is greater than a number of the plurality of second thin-film transistors in the second pixel circuit, and the display panel has a first surface including a first display area and a second surface opposite to the first surface and including a second display area.

The substrate may include a first area and a second area disposed adjacent to the first area, the first pixel circuit and the second pixel circuit may overlap the first area, the first display element may overlap the first area, and the second display element may overlap the second area.

The pixel circuit layer may further include a connection line extending from the first area to the second area and connecting the second pixel circuit to the second display element, and the connection line may include transparent conductive oxide.

The first display element may include a first pixel electrode which has a first thickness and include a plurality of layers, and the second display element may include a second pixel electrode which has a second thickness less than the first thickness and include a transparent conductive oxide.

The pixel circuit layer may further include a first semiconductor layer disposed on the substrate and constituting the plurality of first thin-film transistors, a first insulating layer covering the first semiconductor layer, a second semiconductor layer disposed on the first insulating layer and constituting the plurality of second thin-film transistors, and a second insulating layer covering the second semiconductor layer.

The display panel may further include a first reflective layer disposed between the pixel circuit layer and the first display element to overlap the first display element in a plan view, and a second reflective layer disposed on the display element layer to overlap the second display element in a plan view.

The pixel circuit layer may further include a scan line connected to each of the first pixel circuit and the second pixel circuit, a first data line connected to the first pixel circuit, and a second data line connected to the second pixel circuit and disposed on a different layer from a layer on which the first data line is disposed.

According to one or more embodiments, a display apparatus includes a display panel having a first surface including a first display area and a second surface opposite to the first surface and including a second display area, and a set assembly disposed on the second surface and including an opening exposing the second display area.

The display apparatus may further include a cover panel disposed between the display panel and the set assembly, wherein the cover panel continuously extends on the second surface of the display panel to cover the opening.

The display panel may include a substrate, a pixel circuit layer disposed on the substrate and including a first pixel circuit which includes a plurality of first thin-film transistors and a second pixel circuit which includes a plurality of second thin-film transistors, and a display element layer disposed on the pixel circuit layer and including a first display element connected to the first pixel circuit and a second display element connected to the second pixel circuit. A number of the plurality of first thin-film transistors in the first pixel circuit may be greater than a number of the plurality of second thin-film transistors in the second pixel circuit.

The substrate may include a first area and a second area disposed adjacent to the first area, the first pixel circuit and the second pixel circuit may overlap the first area, the first display element may overlap the first area, and the second display element may overlap the second area.

The pixel circuit layer may further include a connection line extending from the first area to the second area and connecting the second pixel circuit to the second display element, and the connection line may include transparent conductive oxide.

The first display element may include a first pixel electrode which has a first thickness and include a plurality of layers, and the second display element may include a second pixel electrode which has a second thickness less than the first thickness and include a transparent conductive oxide.

The display panel may further include a first reflective layer disposed between the pixel circuit layer the first display element to overlap the first display element in a plan view, and a second reflective layer disposed on the display element layer to overlap the second display element in a plan view.

The display apparatus may be a foldable display which has a folding axis extending across the first surface.

According to one or more embodiments, a display apparatus includes a display panel having a first surface including a first display area and a second surface opposite to the first surface, and a set assembly disposed on the second surface and including an opening exposing the second surface. The first display area includes a component area and a main display area surrounding at least a portion of the component area, the display panel includes a plurality of first subpixels disposed in the main display area and a plurality of second subpixels disposed in the component area, and the component area includes a transmission area adjacent to the plurality of second subpixels. When the display apparatus is folded about a folding axis extending across the first surface, the component area and the opening overlap each other.

The component area may include a first component area and a second component area arranged with the folding axis disposed between the first component area and the second component area. When the display apparatus is folded about the folding axis, the first component area and the second component area may overlap each other.

The first display area may further include a transparent display area disposed on one side of the main display area with the folding axis interposed between the main display area and the transparent display area and having greater light transmittance than light transmittance of the main display area. When the display apparatus is folded about the folding axis, the component area and the transparent display area may overlap each other.

The plurality of first subpixels may include a first subpixel emitting a first color of light, and the plurality of second subpixels may include a second subpixel emitting the first color of light. A planar area of the first subpixel may be greater than a planar area of the second subpixel.

The display apparatus may further include a component overlapping the component area.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a schematic perspective view of a display apparatus according to an embodiment;

FIG. 1B is a perspective view of a first state in which the display apparatus according to an embodiment is folded in one direction;

FIG. 1C is a perspective view of a second state in which the display apparatus according to an embodiment is folded in one direction;

FIGS. 2A and 2B are schematic rear views of the display apparatus of FIG. 1C, according to various embodiments;

FIG. 3A is a schematic cross-sectional view of the display apparatus of FIG. 1A taken along line A-A′ of FIG. 1A;

FIG. 3B is a schematic plan view of a second support layer of the display apparatus of FIG. 3A;

FIG. 4 is an equivalent circuit diagram of a first pixel circuit and a second pixel circuit included in a display panel according to an embodiment;

FIG. 5 is an enlarged view of a portion B of the display panel of FIG. 1A, according to an embodiment;

FIG. 6 is a cross-sectional view of the display panel of FIG. 5 taken along line C-C′ of FIG. 5;

FIG. 7 is an enlarged view of a portion B of the display panel of FIG. 1A, according to another embodiment;

FIG. 8 is a cross-sectional view of the display panel of FIG. 7 taken along line D-D′ of FIG. 7;

FIG. 9 is an enlarged view of a portion E of the display panel of FIG. 1A, according to an embodiment;

FIG. 10 is a cross-sectional view of the display panel of FIG. 9 taken along line F-F′ of FIG. 9;

FIG. 11 is a schematic cross-sectional view of a display apparatus according to another embodiment;

FIG. 12A is a schematic plan view of a display panel included in the display apparatus of FIG. 11;

FIG. 12B is an enlarged view of a portion G of the display panel of FIG. 12A;

FIG. 12C is an enlarged view of a portion H of a first component area of the display panel of FIG. 12A and a portion I of a second component area of the display panel of FIG. 12A;

FIG. 13A is a schematic plan view of the display panel of FIG. 12A in a folded state;

FIG. 13B is an enlarged view of a portion J of the display panel of FIG. 13A;

FIGS. 14A and 14B are plan views of a second subpixel arrangement structure of a component area, according to various embodiments;

FIGS. 15A, 15B, 15C, and 15D are enlarged views of a portion G of the display panel of FIG. 12A and a portion H of the display panel of FIG. 12A, according to various embodiments;

FIG. 16A is a schematic perspective view of a display apparatus according to another embodiment in an unfolded state;

FIG. 16B is a schematic perspective view of the display apparatus according to another embodiment in a folded state;

FIG. 17 is a schematic cross-sectional view of a display apparatus according to another embodiment;

FIG. 18A is a schematic plan view of a display panel included in the display apparatus of FIG. 17;

FIG. 18B is an enlarged view of a portion K of a main display area of the display panel of FIG. 18A, a portion L of a component area of the display panel of FIG. 18A, and a portion M of a transparent display area of the display panel of FIG. 18A;

FIG. 19A is a schematic plan view of the display panel of FIG. 18A in a folded state; and

FIG. 19B is an enlarged view of a portion N of the display panel of FIG. 19A.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Hereinafter, effects and features of the disclosure and a method for accomplishing them will be described more fully with reference to the accompanying drawings, in which embodiments of the present disclosure are shown. The disclosure may, however, be embodied in many different forms and should not be construed as limited to the embodiments set forth herein.

One or more embodiments of the disclosure will be described below in more detail with reference to the accompanying drawings. Those components that are the same as or are in correspondence with each other are rendered the same reference numeral regardless of the figure number, and redundant explanations are omitted.

It will be understood that although the terms “first,” “second,” etc. may be used herein to describe various components, these components should not be limited by these terms. These components are only used to distinguish one component from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on” another layer, region, or component, it can be directly or indirectly formed on the other layer, region, or component. That is, for example, intervening layers, regions, or components may be present.

Sizes of elements in the drawings may be exaggerated for convenience of explanation. For example, since sizes and thicknesses of components in the drawings are arbitrarily illustrated for convenience of explanation, embodiments of the disclosure are not limited thereto.

When a certain embodiment may be implemented differently, a specific process order may be performed differently from the described order. For example, two consecutively described processes may be performed substantially at the same time or performed in an order opposite to the described order.

It will also be understood that when a layer, region, or component is referred to as being “connected” or “coupled” to another layer, region, or component, it can be directly connected or coupled to the other layer, region, or component or intervening layers, regions, or components may be present. For example, when a layer, region, or component is referred to as being “electrically connected” or “electrically coupled” to another layer, region, or component, it can be directly electrically connected or coupled to the other layer, region, or component or intervening layers, regions, or components may be present.

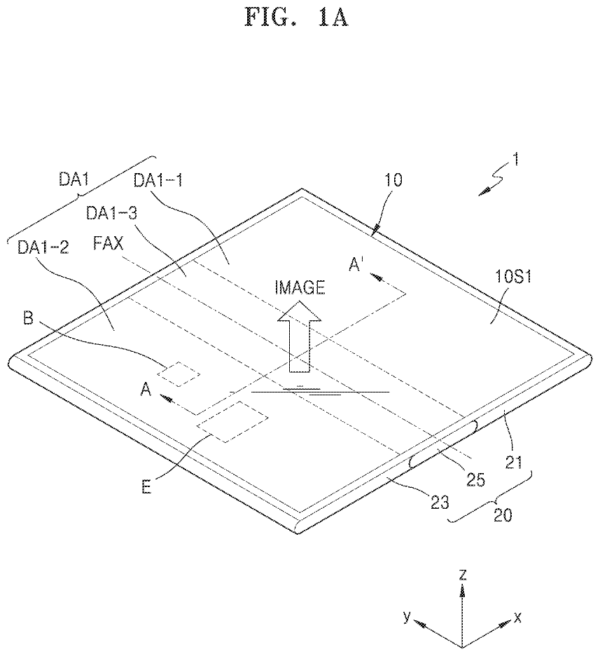

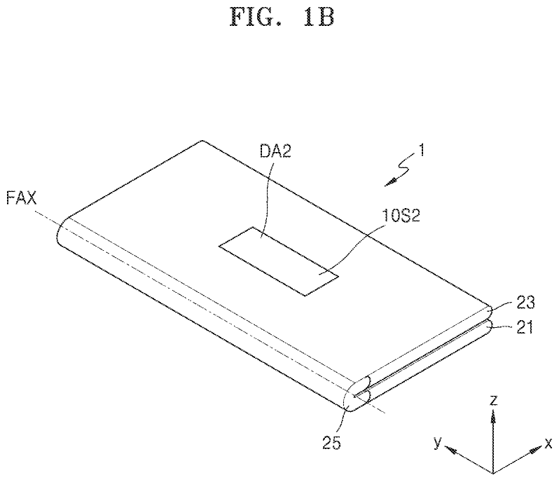

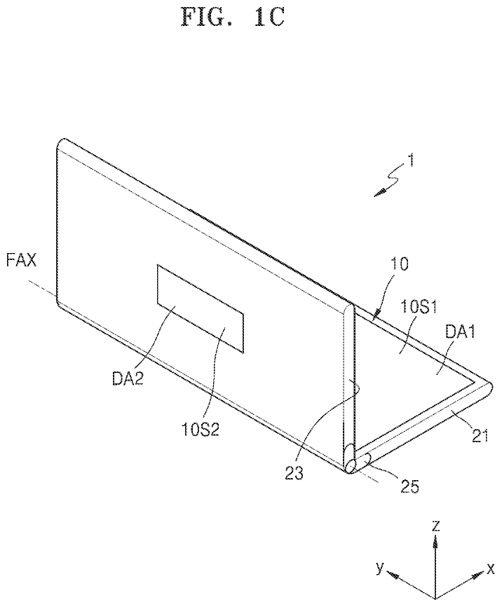

FIG. 1A is a schematic perspective view of a display apparatus 1 according to an embodiment. FIG. 1B is a perspective view of a first state where the display apparatus 1 according to an embodiment is folded in one direction. FIG. 1C is a perspective view of a second state where the display apparatus 1 according to an embodiment is folded in one direction.

Referring to FIGS. 1A, 1B, and 1C, the display apparatus 1 may display an image. According to an embodiment, the display apparatus 1 may be a portable display apparatus, such as a mobile phone, a smartphone, a tablet personal computer (PC), a mobile communication terminal, an electronic notebook, an electronic book, a portable multimedia player (PMP), a navigation device, and an ultra mobile PC (UMPC). According to another embodiment, the display apparatus 1 may be a wearable display apparatus such as a smart watch or a watch phone. According to another embodiment, the display apparatus 1 may also be a center information display (CID) of the center fascia or dashboard of an automobile, a room minor display that replaces the side mirror of an automobile, and a display arranged on the rear side of a front seat to serve as an entertainment device for back seat passengers of automobiles. According to another embodiment, the display apparatus 1 may be a large display apparatus including a large display. FIGS. 1A, 1B, and 1C illustrate a tablet PC, and a case where the display apparatus 1 is a tablet PC will be described in detail.

The display apparatus 1 may be folded. According to an embodiment, the display apparatus 1 may be folded about a folding axis FAX. The display apparatus 1 may include a display panel 10 and a case 20. The display panel 10 may include a first surface 10S1 and a second surface 10S2. The second surface 10S2 may be a surface opposite to the first surface 10S1. The first surface 10S1 may include a first display area DA1. The second surface 10S2 may include a second display area DA2. Accordingly, the display panel 10 may display an image on the first surface 10S1 and may display an image on the second surface 10S2.

The first display area DA1 may include a first portion area DA1-1, a second portion area DA1-2, and a third portion area DA1-3. The third portion area DA1-3 may be disposed between the first portion area DA1-1 and the second portion area DA1-2. The third portion area DA1-3 may overlap the folding axis FAX.

The case 20 may protect the display panel 10. The case 20 may house the display panel 10. The case 20 may include a first portion 21, a second portion 23, and a third portion 25 that protect the display panel 10. The first portion 21 may overlap the first portion area DA1-1 in a plan view. The second portion 23 may overlap the second portion area DA1-2 in a plan view. The third portion 25 may overlap the third portion area DA1-3 in a plan view. According to an embodiment, the second portion 23 may expose the second display area DA2. For example, a portion of the second portion 23 that overlaps the second display area DA2 may be transparent. As another example, the second portion 23 may include an opening that exposes the second display area DA2. The case 20 may be folded about the folding axis FAX disposed between the first portion 21 and the second portion 23. According to an embodiment, the third portion 25 may have a hinge structure.

Referring to FIGS. 1A, 1B, and 1C, the display panel 10 may be folded together with the case 20. Referring to FIGS. 1A and 1B, the first portion area DA1-1 and the second portion area DA1-2 of the display panel 10 folded about the folding axis FAX extending across the first surface 10S1 may face each other in a first state. According to another embodiment, the display apparatus 1 may be folded such that the first portion 21 of the case 20 and the second portion 23 of the case 20 may face each other. Referring to FIG. 1C, the display apparatus 1 may be folded such that extending directions of the first portion 21 of the case 20 and the second portion 23 of the case 20 may intersect each other.

FIGS. 1A, 1B, and 1C illustrate only one folding axis FAX. However, according to an embodiment, the display apparatus 1 may include a plurality of folding axes FAX. FIGS. 1A, 1B, and 1C illustrate that the folding axis FAX extends in the y direction. However, according to another embodiment, the folding axis FAX may extend in an x direction or may extend in a direction intersecting the x direction and the y direction.

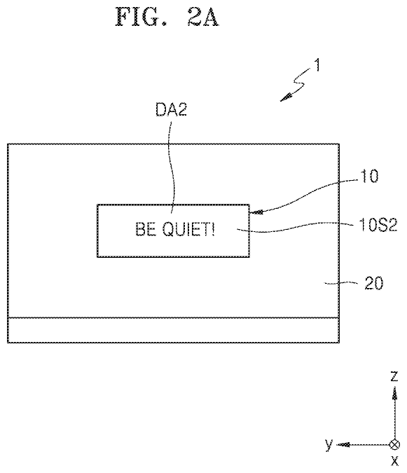

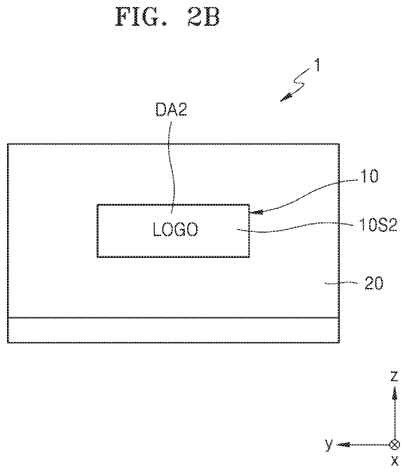

FIGS. 2A and 2B are schematic rear views of the display apparatus 1 of FIG. 1C, according to various embodiments. Reference numerals in FIGS. 2A and 2B that are the same as the reference numerals in FIG. 1C denote the same elements, and thus repeated descriptions thereof are omitted.

Referring to FIGS. 2A and 2B, the display apparatus 1 may include the display panel 10 and the case 20. The display panel 10 may include a first surface including a first display area, and a second surface 10S2 opposite to the first surface and including the second display area DA2.

The second display area DA2 may display an image. Referring to FIG. 2A, the second display area DA2 may display a message. For example, the display apparatus 1 may provide an image to a user through the first display area. The display apparatus 1 may provide a message to the opposite party sitting to face the user through the second display area DA2. Referring to FIG. 2B, the second display area DA2 may display a logo or a trademark.

According to the present embodiment, the display apparatus 1 may include the display panel 10 including the first surface 10S1 including the first display area, and the second surface 10S2 opposite to the first surface and including the second display area DA2. Accordingly, the display apparatus 1 may display an image on the first surface 10S1 and the second surface 10S2 through the display panel 10. No light sources may be needed to be arranged in the case 20.

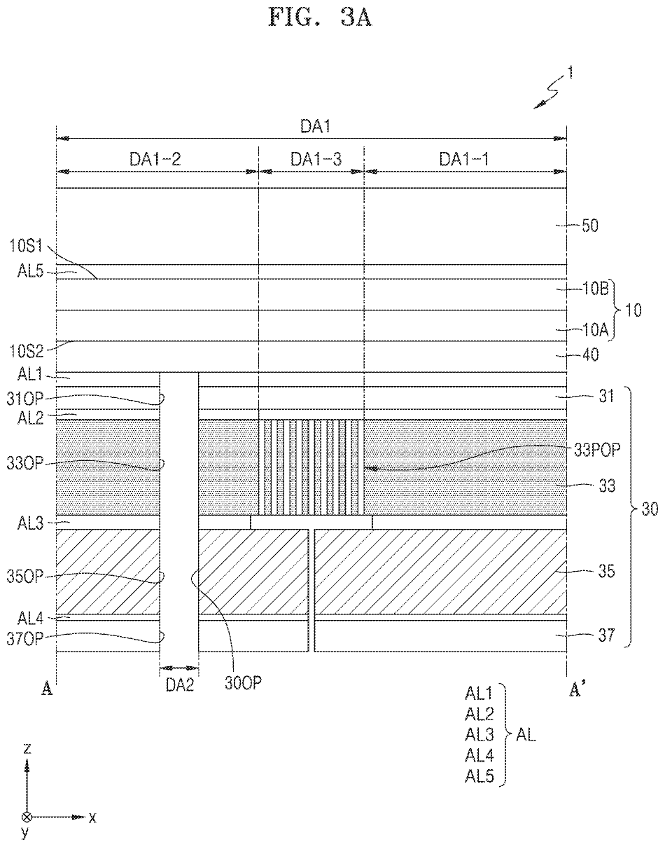

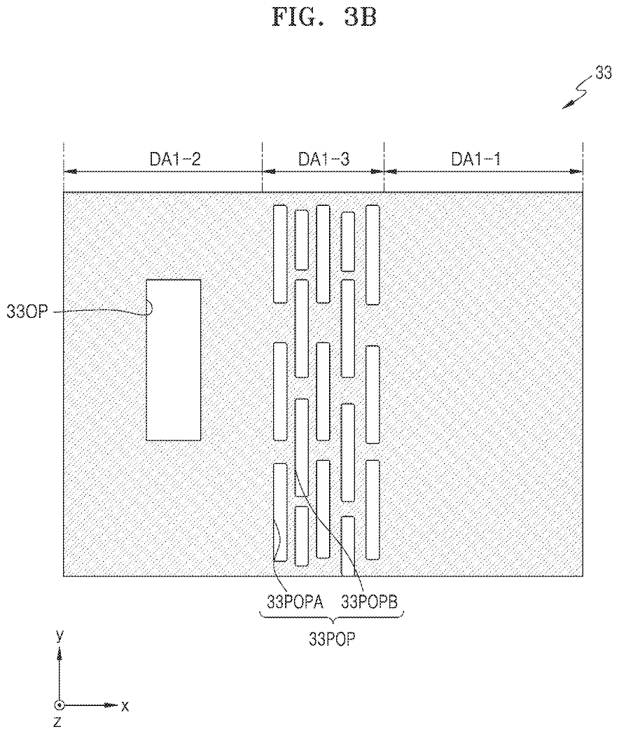

FIG. 3A is a schematic cross-sectional view of the display apparatus 1 of FIG. 1A taken along line A-A′. FIG. 3B is a schematic plan view of a second support layer 33 of the display apparatus 1 of FIG. 3A.

Referring to FIGS. 3A and 3B, the display apparatus 1 may include a display panel 10, a set assembly 30, a cover panel 40, a cover window 50, and an adhesive layer AL. The display panel 10 may display an image. According to an embodiment, the display panel 10 may include the first surface 10S1 and the second surface 10S2. The first surface 10S1 and the second surface 10S2 may be opposite to each other. The first surface 10S1 may include the first display area DA1 displaying an image. The first display area DA1 may include the first portion area DA1-1, the second portion area DA1-2, and the third portion area DA1-3. The third portion area DA1-3 may be disposed between the first portion area DA1-1 and the second portion area DA1-2. The second surface 10S2 may include the second display area DA2 displaying an image. The display panel 10 may include a first panel layer 10A and a second panel layer 10B.

The first panel layer 10A may emit light. The first panel layer 10A may include a substrate, a pixel circuit layer including a pixel circuit, a display element layer including a display element, an encapsulation layer, and a touch sensor layer which are sequentially stacked on one another. The first panel layer 10A may emit light by using the display element. According to an embodiment, the display element may be an organic light-emitting diode including an organic emission layer. Alternatively, the display element may be a light-emitting diode (LED). The size of the LED may be microscale or nanoscale. For example, the LED may be a micro-LED. As another example, the LED may be a nanorod LED. The nanorod LED may include gallium nitride (GaN). According to an embodiment, a color converting layer may be arranged on the nanorod LED. The color converting layer may include quantum dots. Alternatively, the display element may be a quantum dot light-emitting diode including a quantum dot emission layer. Alternatively, the display element may be an inorganic light-emitting diode including an inorganic semiconductor.

The second panel layer 10B may be located on the first panel layer 10A. The second panel layer 10B may include an anti-reflective layer. The anti-reflective layer may reduce the reflectance of light incident upon the first panel layer 10A. The anti-reflective layer may increase the color purity of light emitted by the first panel layer 10A. According to an embodiment, the anti-reflective layer may include a color filer and a black matrix. According to another embodiment, the anti-reflective layer may include a phase retarder and/or a polarizer. The phase retarder may be of a film type or liquid coating type, and may include a λ/2 phase retarder and/or a λ/4 phase retarder. The polarizer may also be of a film type or liquid coating type. The film type polarizer may include a stretchable synthetic resin film, and the liquid coating type polarizer may include liquid crystals arranged in a certain arrangement. The phase retarder and the polarizer may further include protective films, respectively. According to another embodiment, the anti-reflective layer may include a destructive interference structure. The destructive interference structure may include a first reflective layer and a second reflective layer disposed on different layers. First reflected light and second reflected light respectively reflected by the first reflective layer and the second reflective layer may destructively interfere with each other, and thus the reflectance of external light may be reduced.

The set assembly 30 may be located on the second surface 10S2. The set assembly 30 may support the display panel 10. The set assembly 30 may include an opening 30OP overlapping the second surface 10S2. According to an embodiment, the opening 30OP of the set assembly 30 may expose the second display area DA2. Accordingly, the display panel 10 may emit light through the opening 30OP, and the display apparatus 1 may display an image through the opening 30OP. The set assembly 30 may include a first support layer 31, a second support layer 33, a third support layer 35, and a fourth support layer 37.

The first support layer 31 may be located on the second surface 10S2. The first support layer 31 may support the display panel 10. The first support layer 31 may include a first support layer opening 310P. According to an embodiment, the first support layer opening 310P may expose the second display area DA2. According to an embodiment, the first support layer 31 may include at least one of glass, plastic, and a metal material. When the first support layer 31 includes a metal material, the first support layer 31 may be a metal plate. According to an embodiment, the first support layer 31 may include polymer resin.

The second support layer 33 may be located below the first support layer 31. The second support layer 33 may protect the display panel 10. The second support layer 33 may include a folding opening pattern 33POP overlapping the third portion area DA1-3. A shape of the folding opening pattern 33POP may vary when the display apparatus 1 is folded. According to an embodiment, the folding opening pattern 33POP may include a first folding opening pattern 33POPA and a second folding opening pattern 33POPB.

The folding opening pattern 33POP may include a plurality of first folding opening patterns 33POPA. The plurality of first folding opening pattern 33POPA may be spaced apart from one another in the y direction of FIG. 3B with a plurality of discontinuous portions between the plurality of first folding opening pattern 33POPA. The folding opening pattern 33POP may include a plurality of second folding opening patterns 33POPB. The plurality of second folding opening patterns 33POPB may be spaced apart from one another in the y direction of FIG. 3B with a plurality of discontinuous portions between the plurality of second folding opening pattern 33POPB. According to an embodiment, the plurality of first folding opening patterns 33POPA and the plurality of second folding opening patterns 33POPB may be alternately arranged in the x direction of FIG. 3B. According to an embodiment, the first folding opening pattern 33POPA may overlap edges of the second folding opening pattern 33POPB and the second folding opening pattern 33POPB may overlap edges of the first folding opening pattern 33POPA in the x direction of FIG. 3B.

The second support layer 33 may include a second support layer opening 330P. According to an embodiment, the second support layer opening 330P may expose the second display area DA2.

The second support layer 33 may include at least one of glass, plastic, and a metal. According to an embodiment, the second support layer 33 may include polyurethane or may include carbon fiber reinforced plastic. According to another embodiment, the second support layer 33 may include at least one of stainless steel, invar, nickel (Ni), cobalt (Co), a nickel alloy, and a nickel-cobalt alloy. According to an embodiment, the second support layer 33 may include austenitic stainless steel.

The third support layer 35 may be located below the second support layer 33. The third support layer 35 may include a third support layer opening 350P. According to an embodiment, the third support layer opening 350P may expose the second display area DA2. According to an embodiment, the third support layer 35 may be include a discontinuous portion which separate the third support layer 35 into two portions in the third portion area DA1-3. Accordingly, the display apparatus 1 may prevent or reduce generation of cracks in the third support layer 35 when being folded. According to an embodiment, the third support layer 35 may include a digitizer. According to an embodiment, the third support layer 35 may include at least one of glass, plastic, and a metal material.

The fourth support layer 37 may be located below the third support layer 35. The fourth support layer 37 may protect the third support layer 35. The fourth support layer 37 may transmit heat generated by the display apparatus 1 to the outside. According to an embodiment, the fourth support layer 37 may include a metal having high heat transfer efficiency. According to another embodiment, the fourth support layer 37 may include graphite. When the fourth support layer 37 includes graphite, the fourth support layer 37 may be thinner than when including a metal. The fourth support layer 37 may include a fourth support layer opening 370P. According to an embodiment, the fourth support layer opening 370P may expose the second display area DA2.

According to an embodiment, the opening 30OP of the set assembly 30 may include the first support layer opening 310P, the second support layer opening 330P, the third support layer opening 350P, and the fourth support layer opening 370P which expose the second display area DA2.

The cover panel 40 may be located between the display panel 10 and the set assembly 30. According to an embodiment, the cover panel 40 may continuously extend on the second surface 10S2. Accordingly, even when the set assembly 30 includes the opening 30OP, the cover panel 40 may protect the display panel 10. According to an embodiment, a portion of the cover panel 40 that overlaps the second display area DA2 may be transparent. According to an embodiment, the cover panel 40 may include polymer resin such as polyethylene terephthalate or polyimide.

The cover window 50 may be located on the display panel 10. According to an embodiment, the cover window 50 may be arranged on the first surface 10S1. The cover window 50 may protect the display panel 10. According to an embodiment, the cover window 50 may be a flexible window. Accordingly, the cover window 50 may protect the display panel 10 while being easily bent along an external force without generating cracks and the like. The cover window 50 may include glass, sapphire or plastic. For example, the cover window 50 may be tempered glass (e.g., ultra-thin glass) or colorless polyimide. According to an embodiment, the cover window 50 may have a structure in which a flexible polymer layer is arranged on one surface of a glass substrate, or may only include a polymer layer.

The adhesive layer AL may be disposed between a first component and a second component of the display apparatus 1. The adhesive layer AL may attach the first component to the second component. According to an embodiment, the adhesive layer AL may be a pressure sensitive adhesive. According to another embodiment, the adhesive layer AL may include an optically clear adhesive. The adhesive layer AL may include a first adhesive layer ALL a second adhesive layer AL2, a third adhesive layer AL3, a fourth adhesive layer AL4, and a fifth adhesive layer AL5.

The first adhesive layer AL1 may be located between the set assembly 30 and the cover panel 40. The first adhesive layer AL1 may attach the set assembly 30 to the cover panel 40. According to an embodiment, the first adhesive layer AL1 may include an opening that is disposed corresponding to the opening 30OP of the set assembly 30. According to an embodiment, the first adhesive layer AL1 may be arranged not to overlap the third portion area DA1-3. According to another embodiment, the first adhesive layer AL1 may be arranged to overlap the third portion area DA1-3.

The second adhesive layer AL2 may be disposed between the first support layer 31 and the second support layer 33. The second adhesive layer AL2 may attach the first support layer 31 to the second support layer 33. According to an embodiment, the second adhesive layer AL2 may include an opening that is disposed corresponding to the opening 30OP of the set assembly 30.

The third adhesive layer AL3 may be disposed between the second support layer 33 and the third support layer 35. The third adhesive layer AL3 may attach the second support layer 33 to the third support layer 35. According to an embodiment, the third adhesive layer AL3 may include an opening that is disposed corresponding to the opening 30OP of the set assembly 30. According to an embodiment, the third adhesive layer AL3 may be arranged not to overlap the third portion area DA1-3. According to another embodiment, the third adhesive layer AL3 may be arranged to overlap the third portion area DA1-3.

The fourth adhesive layer AL4 may be disposed between the third support layer 35 and the fourth support layer 37. The fourth adhesive layer AL4 may attach the third support layer 35 to the fourth support layer 37. According to an embodiment, the fourth adhesive layer AL4 may include an opening that is disposed corresponding to the opening 30OP of the set assembly 30. According to an embodiment, a portion of the fourth adhesive layer AL4 that overlaps the first portion area DA1-1 may be spaced apart from a portion of the fourth adhesive layer AL4 that overlaps the second portion area DA1-2.

The fifth adhesive layer AL5 may be disposed between the display panel 10 and the cover window 50. The fifth adhesive layer AL5 may attach the display panel 10 to the cover window 50.

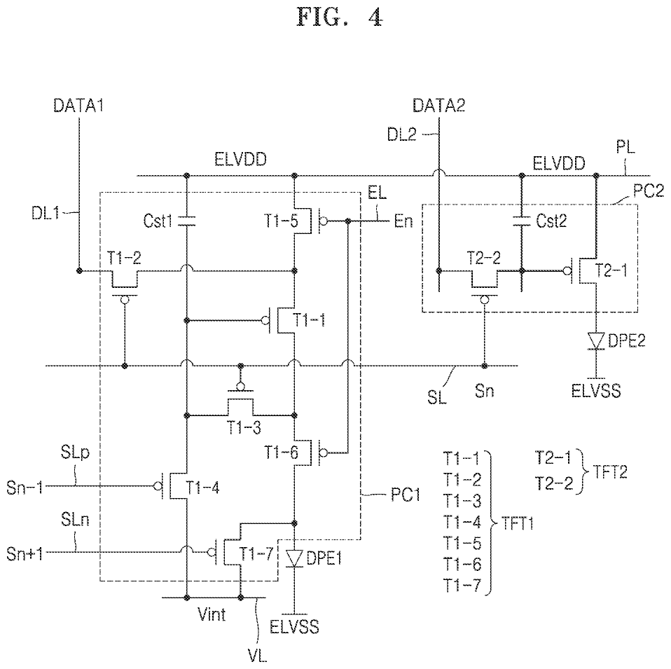

FIG. 4 is an equivalent circuit diagram of a first pixel circuit PC1 and a second pixel circuit PC2 included in a display panel according to an embodiment.

Referring to FIG. 4, the first pixel circuit PC1 may include a plurality of first thin-film transistors TFT1, and the second pixel circuit PC2 may include a plurality of second thin-film transistors TFT2. According to an embodiment, the number of first thin-film transistors TFT1 in the first pixel circuit PC1 may be greater than the number of second thin-film transistors TFT2 in the second pixel circuit PC2. For example, in the second pixel circuit PC2, the number of second thin-film transistors TFT2 may be 2. In this case, in the first pixel circuit PC1, the number of first thin-film transistors TFT1 may be three or more. A case where the number of second thin-film transistors TFT2 in the second pixel circuit PC2 is two and the number of first thin-film transistors TFT1 in the first pixel circuit PC1 is seven will now be described.

The first pixel circuit PC1 may include a first driving thin-film transistor T1-1, a first switching thin-film transistor T1-2, a compensating thin-film transistor T1-3, a first initializing thin-film transistor T1-4, an operation control thin-film transistor T1-5, a light-emission control thin-film transistor T1-6, a second initializing thin-film transistor T1-7, and a first storage capacitor Cst1. The first display element DPE1 connected to the first pixel circuit PC1 may emit red light, green light, or blue light, or may emit red light, green light, blue light, or white light.

A driving drain electrode of the first driving thin-film transistor T1-1 may be connected to the first display element DPE1 via the light-emission control thin-film transistor T1-6. The first driving thin-film transistor T1-1 may receive a first data signal DATA1 in response to a switching operation of the first switching thin-film transistor T1-2 and may supply a driving current to the first display element DPE1.

A switching gate electrode of the first switching thin-film transistor T1-2 may be connected to a scan line SL, and a switching source electrode thereof may be connected to a first data line DLL A switching drain electrode of the first switching thin-film transistor T1-2 may be connected to a driving source electrode of the first driving thin-film transistor T1-1 and a driving voltage line PL via the operation control thin-film transistor T1-5. The first switching thin-film transistor T1-2 may be turned on in response to a scan signal Sn received via the scan line SL and may perform a switching operation of transmitting a first data signal DATA1 received from the first data line DL1 to the driving source electrode of the first driving thin-film transistor T1-1.

A compensating gate electrode of the compensating thin-film transistor T1-3 may be connected to the scan line SL. A compensating source electrode of the compensating thin-film transistor T1-3 may be connected to the driving drain electrode of the first driving thin-film transistor T1-1 and a pixel electrode of the first display element DPE1 via the light-emission control thin-film transistor T1-6. A compensating drain electrode of the compensating thin-film transistor T1-3 may be connected to one electrode of the first storage capacitor Cst1, a first initializing source electrode of the first initializing thin-film transistor T1-4, and a driving gate electrode of the first driving thin-film transistor T1-1. The compensating thin film transistor T1-3 may be turned on in response to the scan signal Sn received via the scan line SL and connect the driving gate electrode and the driving drain electrode of the first driving thin film transistor T1-1 to each other, thus achieving diode-connection of the first driving thin film transistor T1-1.

A first initializing gate electrode of the first initializing thin-film transistor T1-4 may be connected to a previous scan line SLp. A first initializing drain electrode of the first initializing thin-film transistor T1-4 may be connected to an initializing voltage line VL. A first initializing source electrode of the first initializing thin-film transistor T1-4 may be connected to the one electrode of the first storage capacitor Cst1, the compensating drain electrode of the compensating thin film transistor T1-3, and the driving gate electrode of the first driving thin-film transistor T1-1. The first initializing thin-film transistor T1-4 may be turned on in response to a previous scan signal Sn-1 received via the previous scan line SLp and may transmit an initializing voltage Vint to the driving gate electrode of the first driving thin-film transistor T1-1 to thereby initialize a voltage of the driving gate electrode of the first driving thin-film transistor T1-1.

An operation control gate electrode of the operation control thin-film transistor T1-5 may be connected to a light-emission control line EL. An operation control source electrode of the operation control thin-film transistor T1-5 may be connected to the driving voltage line PL. An operation control drain electrode of the operation control thin-film transistor T1-5 may be connected to the driving source electrode of the first driving thin-film transistor T1-1 and the switching drain electrode of the first switching thin-film transistor T1-2.

A light emission control gate electrode of the light-emission control thin-film transistor T1-6 may be connected to the light-emission control line EL. A light emission control source electrode of the light-emission control thin-film transistor T1-6 may be connected to the driving drain electrode of the first driving thin-film transistor T1-1 and the compensating source electrode of the compensating thin-film transistor T1-3. A light emission control drain electrode of the light-emission control thin-film transistor T1-6 may be connected to a pixel electrode of the first display element DPEL The operation control thin-film transistor T1-5 and the light-emission control thin-film transistor T1-6 may be simultaneously turned on in response to a light-emission control signal En received via the light-emission control line EL, and thus a first power supply voltage ELVDD may be transmitted to the first display element DPE1 and driving current may flow in the first display element DPE1.

A second initializing gate electrode of the second initializing thin-film transistor T1-7 may be connected to a next scan line SLn. A second initializing source electrode of the second initializing thin-film transistor T1-7 may be connected to the pixel electrode of the first display element DPE1. A second initializing drain electrode of the second initializing thin-film transistor T1-7 may be connected to the initializing voltage line VL. The second initializing thin-film transistor T1-7 may be turned on in response to a next scan signal Sn+1 received via the next scan line SLn and may initialize the pixel electrode of the first display element DPEL

In FIG. 4, the first initializing thin-film transistor T1-4 and the second initializing thin-film transistor T1-7 are connected to the previous scan line SLp and the next scan line SLn, respectively. However, according to another embodiment, the first initializing thin-film transistor T1-4 and the second initializing thin-film transistor T1-7 may be both connected to the previous scan line SLp to operate in response to the previous scan signal Sn-1.

Another electrode of the first storage capacitor Cst1 may be connected to the driving voltage line PL. The one electrode of the first storage capacitor Cst may be connected to the driving gate electrode of the first driving thin-film transistor T1-1, the compensating drain electrode of the compensating thin film transistor T1-3, and the first initializing source electrode of the first initializing thin-film transistor T1-4.

An opposite electrode (for example, a cathode) of the first display element DPE1 may receive a second power supply voltage ELVSS. The first display element DPE1 may receive the driving current from the first driving thin-film transistor T1-1 and emit light.

The second pixel circuit PC2 may include a second driving thin-film transistor T2-1, a second switching thin-film transistor T2-2, and a second storage capacitor Cst2. The second display element DPE2 connected to the second pixel circuit PC2 may emit red light, green light, or blue light, or may emit red light, green light, blue light, or white light.

The second switching thin-film transistor T2-2 may be connected to the scan line SL and a second data line DL2, and may be turned on in response to the scan signal Sn received via the scan line SL and transmit a second data signal DATA2 received via the second data line DL2 to the second driving thin-film transistor T2-1. According to an embodiment, the scan line SL may be connected to each of the first pixel circuit PC1 and the second pixel circuit PC2. Accordingly, both the first pixel circuit PC1 and the second pixel circuit PC2 may receive the scan signal Sn. According to an embodiment, the second pixel circuit PC2 may receive the second data signal DATA2 from the second data line DL2, and the first pixel circuit PC1 may receive the first data signal DATA1 from the first data line DL1. Accordingly, the first pixel circuit PC1 and the second pixel circuit PC2 may operate independently.

The second storage capacitor Cst2 may be connected to the second switching thin-film transistor T2-2 and the driving voltage line PL, and may store a voltage corresponding to a difference between a voltage received from the second switching thin-film transistor T2-2 and the first power supply voltage ELVDD supplied to the driving voltage line PL.

The second driving thin-film transistor T2-1 may be connected to the driving voltage line PL and a pixel electrode of the second display element DPE2, and may control a driving current flowing from the driving voltage line PL to the second display element DPE2 in accordance with a voltage stored in the second storage capacitor Cst2. The second display element DPE2 may emit light having a certain brightness according to the driving current. An opposite electrode (for example, a cathode) of the second display element DPE2 may receive the second power supply voltage ELVSS.

In FIG. 4, the second pixel circuit PC2 includes two thin-film transistors and one storage capacitor. However, the second pixel circuit PC2 may include three or more thin-film transistors.

The first display element DPE1 may emit light for providing an image to the first display area DA1 of FIG. 1A, and the second display element DPE2 may emit light for providing an image to the second display area DA2 of FIG. 1B. The first display element DPE1 may be connected to the first pixel circuit PC1 including the plurality of first thin-film transistor TFT1, the number of which is greater than that of second thin-film transistors TFT2 included in the second pixel circuit PC2. Accordingly, the first display area DA1 may provide a high quality image. Because the second display element DPE2 provides a relatively simpler image in the second display area DA2 than in the first display area DA1, the second display element DPE2 may be connected to the second pixel circuit PC2 including the plurality of second thin-film transistor TFT2, the number of which is less than that of first thin-film transistors TFT1 included in the first pixel circuit PC1. Accordingly, the area of the second pixel circuit PC2 in the display panel may be reduced.

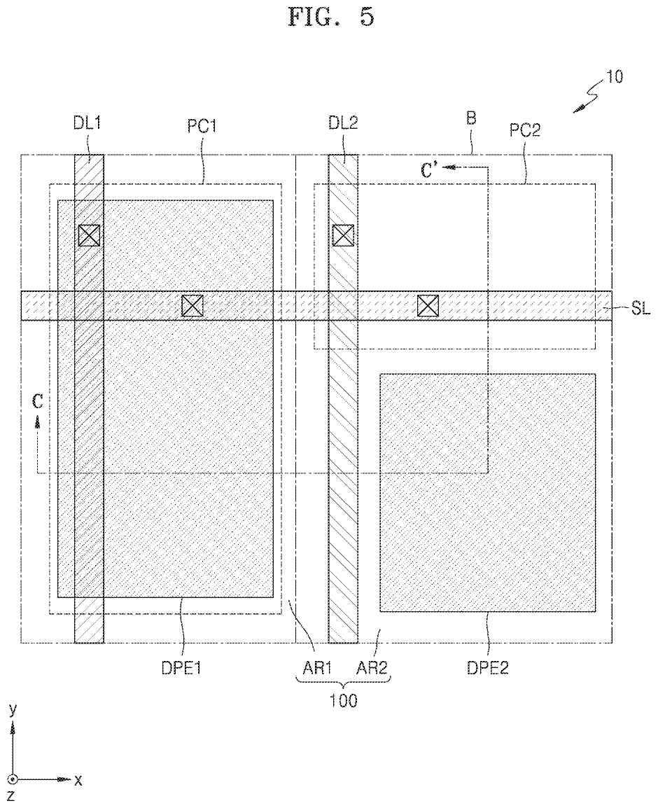

FIG. 5 is an enlarged view of a portion B of the display panel 10 of FIG. 1A, according to an embodiment. Reference numerals in FIG. 5 that are the same as the reference numerals in FIG. 4 denote the same elements, and thus repeated descriptions thereof are omitted.

Referring to FIG. 5, the display panel 10 may display an image. The display panel 10 may include a substrate 100, the first pixel circuit PC1, the second pixel circuit PC2, the scan line SL, the first data line DL1, the second data line DL2, the first display element DPE1, and the second display element DPE2. The substrate 100 may include a first area AR1 and a second area AR2. The first area AR1 and the second area AR2 may be disposed adjacent to each other.

The first pixel circuit PC1 and the second pixel circuit PC2 may be arranged on the substrate 100. According to an embodiment, the first pixel circuit PC1 may overlap the first area AR1. According to an embodiment, the second pixel circuit PC2 may overlap at least one of the first area AR1 and the second area AR2. For example, the second pixel circuit PC2 may overlap the second area AR2. According to an embodiment, the first pixel circuit PC1 may include a plurality of first thin-film transistors, and the second pixel circuit PC2 may include a plurality of second thin-film transistors. According to an embodiment, the number of first thin-film transistors in the first pixel circuit PC1 may be greater than the number of second thin-film transistors in the second pixel circuit PC2. Accordingly, the area of the second pixel circuit PC2 may be less than that of the first pixel circuit PC1.

The scan line SL may be located on the substrate 100. The scan line SL may extend in an x direction of FIG. 5. According to an embodiment, the first pixel circuit PC1 and the second pixel circuit PC2 may be each connected to the scan line SL. Accordingly, both the first pixel circuit PC1 and the second pixel circuit PC2 may receive an identical scan signal.

The first data line DL1 may be located on the substrate 100. According to an embodiment, the first data line DL1 may overlap the first area AR1. The first data line DL1 may extend in a y direction of FIG. 5. The first data line DL1 may be connected to the first pixel circuit PC1. According to an embodiment, the first data line DL1 may transmit a first data signal to the first pixel circuit PC1.

The second data line DL2 may be located on the substrate 100. According to an embodiment, the second data line DL2 may overlap at least one of the first area AR1 and the second area AR2. The second data line DL2 may extend in the y direction of FIG. 5. The second data line DL2 may be connected to the second pixel circuit PC2. According to an embodiment, the second data line DL2 may transmit a second data signal to the second pixel circuit PC2. Accordingly, the first pixel circuit PC1 and the second pixel circuit PC2 may operate independently.

According to an embodiment, the first data line DL1 and the second data line DL2 may be disposed on different layers. In other words, one of the first data line DL1 and the second data line DL2 may be disposed under an insulating layer, and the other of the first data line DL1 and the second data line DL2 may be disposed over the insulating layer. According to another embodiment, the first data line DL1 and the second data line DL2 may be disposed on the same layer. In other words, the first data line DL1 and the second data line DL2 may be each disposed between a lower insulating layer and an upper insulating layer.

The first display element DPE1 and the second display element DPE2 may be located on the substrate 100. Although not shown in FIG. 5, the first display element DPE1 may be connected to the first pixel circuit PC1, and the second display element DPE2 may be connected to the second pixel circuit PC2. According to an embodiment, the first display element DPE1 may overlap the first area AR1. The second display element DPE2 may overlap the second area AR2. According to an embodiment, the first display element DPE1 may overlap the first pixel circuit PC1. The first display element DPE1 may emit light in a z direction of FIG. 5 so that the first display area DA1 (see FIG. 1A) of the display panel 10 displays an image. The second display element DPE2 may not overlap the second pixel circuit PC2. Accordingly, the second display element DPE2 may emit light in a −z direction which is opposite to the z-direction of FIG. 5 so that the second display area DA2 (see FIG. 1B) of the display panel 10 displays an image.

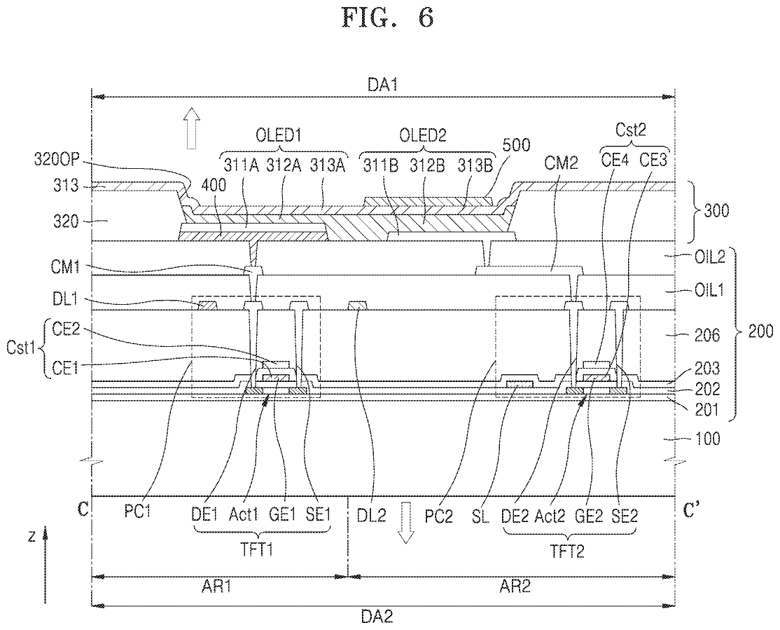

FIG. 6 is a cross-sectional view of the display panel 10 of FIG. 5 taken along line C-C′ of FIG. 5. Reference numerals in FIG. 6 that are the same as the reference numerals in FIG. 5 denote the same elements, and thus repeated descriptions thereof are omitted.

Referring to FIG. 6, the display panel 10 may include a first surface including the first display area DA1 and a second surface including the second display area DA2. The first display area DA1 may display an image in a z direction of FIG. 6. The second display area DA2 may display an image in a −z direction of FIG. 6. The display panel 10 may include the substrate 100, a pixel circuit layer 200, a display element layer 300, a first reflective layer 400, and a second reflective layer 500.

The substrate 100 may include the first area AR1 and the second area AR2. The first area AR1 and the second area AR2 may be disposed adjacent to each other. The substrate 100 may include glass or polymer resin such as polyethersulfone, polyacrylate, polyetherimide, polyethylene naphthalate, polyethylene terephthalate, polyphenylene sulfide, polyimide, polycarbonate, cellulose triacetate, or cellulose acetate propionate. According to an embodiment, the substrate 100 may have a multi-layered structure including a base layer including the aforementioned polymer resin and a barrier layer (not shown). The substrate 100 including polymer resin may have flexible, rollable, and bendable characteristics.

The pixel circuit layer 200 may be located on the substrate 100. The pixel circuit layer 200 may include the first pixel circuit PC1, the second pixel circuit PC2, the scan line SL, the first data line DL1, the second data line DL2, a first connection electrode CM1, a second connection electrode CM2, a buffer layer 201, a first insulating layer 202, a gate insulating layer 203, an interlayer insulating layer 206, a first organic insulating layer OIL1, and a second organic insulating layer OIL2.

The first pixel circuit PC1 may be located in the first area AR1. The first pixel circuit PC1 may include a first thin-film transistor TFT1 and a first storage capacitor Cst1. The first thin-film transistor TFT1 may include a first semiconductor layer Act1, a first gate electrode GE1, a first source electrode SE1, and a first drain electrode DEL The first storage capacitor Cst1 may include a first lower electrode CE1 and a first upper electrode CE2. According to an embodiment, the first pixel circuit PC1 may include a plurality of first thin-film transistors TFT1.

The second pixel circuit PC2 may be located in at least one of the first area AR1 and the second area AR2. For example, the second pixel circuit PC2 may be located in the second area AR2. The second pixel circuit PC2 may include a second thin-film transistor TFT2 and a second storage capacitor Cst2. The second thin-film transistor TFT2 may include a second semiconductor layer Act2, a second gate electrode GE2, a second source electrode SE2, and a second drain electrode DE2. The second storage capacitor Cst2 may include a second lower electrode CE3 and a second upper electrode CE4. According to an embodiment, the second pixel circuit PC2 may include a plurality of second thin-film transistors TFT2. Although not shown in FIG. 6, the number of first thin-film transistors TFT1 in the first pixel circuit PC1 may be greater than the number of second thin-film transistors TFT2 in the second pixel circuit PC2.

The buffer layer 201 may be located on the substrate 100. The buffer layer 201 may include an inorganic insulating material, such as silicon nitride (SiNₓ), silicon oxynitride (SiON), and/or silicon oxide (SiO₂), and may have a single-layer or multi-layer structure including the inorganic insulating material.

The first semiconductor layer Act1 and the second semiconductor layer Act2 may be located on the buffer layer 201. At least one of the first semiconductor layer Act1 and the second semiconductor layer Act2 may include a silicon semiconductor. At least one of the first semiconductor layer Act1 and the second semiconductor layer Act2 may include polysilicon. Alternatively, at least one of the first semiconductor layer Act1 and the second semiconductor layer Act2 may include amorphous silicon. According to some embodiments, at least one of the first semiconductor layer Act1 and the second semiconductor layer Act2 may include an oxide semiconductor or an organic semiconductor. At least one of the first semiconductor layer Act1 and the second semiconductor layer Act2 may include a channel region, and a source region and a drain region respectively arranged on both sides of the channel region.

The first insulating layer 202 may cover the first semiconductor layer Act1 and the second semiconductor layer Act2. The first insulating layer 202 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

The first gate electrode GE1 and the second gate electrode GE2 may be located on the first insulating layer 202. The first gate electrode GE1 may overlap the first semiconductor layer Act1. The second gate electrode GE2 may overlap the second semiconductor layer Act2. At least one of the first gate electrode GE1 and the second gate electrode GE2 may include a low-resistance metal material. At least one of the first gate electrode GE1 and the second gate electrode GE2 may include a conductive material including, for example, molybdenum (Mo), aluminum (Al), copper (Cu), and titanium (Ti), and may have a multi-layer or single-layer structure including the aforementioned materials.

The gate insulating layer 203 may cover the first gate electrode GE1 and the second gate electrode GE2. The gate insulating layer 203 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

The first upper electrode CE2 and the second upper electrode CE4 may be located on the gate insulating layer 203. The first upper electrode CE2 may overlap the first gate electrode GE1. In this case, the first upper electrode CE2 and the first gate electrode GE1 may overlap each other with the gate insulating layer 203 disposed therebetween to constitute the first storage capacitor Cst1. According to an embodiment, the first gate electrode GE1 may function as the first lower electrode CE1 of the first storage capacitor Cst1. Thus, the first storage capacitor Cst1 and the first thin-film transistor TFT1 may overlap each other. According to another embodiment, the first storage capacitor Cst1 and the first thin-film transistor TFT1 may not overlap each other.

The second upper electrode CE4 may overlap the second gate electrode GE2. In this case, the second upper electrode CE4 and the second gate electrode GE2 may overlap each other with the gate insulating layer 203 disposed therebetween to constitute the second storage capacitor Cst2. According to an embodiment, the second gate electrode GE2 may function as the second lower electrode CE3 of the second storage capacitor Cst2. Thus, the second storage capacitor Cst2 and the second thin-film transistor TFT2 may overlap each other. According to another embodiment, the second storage capacitor Cst2 and the second thin-film transistor TFT2 may not overlap each other.

At least one of the first and second upper electrodes CE2 and CE4 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may each be a single layer or multi-layer including the aforementioned materials.

The interlayer insulating layer 206 may cover the first upper electrode CE2 and the second upper electrode CE4. The interlayer insulating layer 206 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO), or the like. The interlayer insulating layer 206 may be a single layer or multi-layer including the aforementioned inorganic insulating materials.

Although not shown in FIG. 6, the scan line SL may be connected to each of the first pixel circuit PC1 and the second pixel circuit PC2. The scan line SL may be located on the first insulating layer 202. According to an embodiment, the scan line SL may be disposed between the first insulating layer 202 and the gate insulating layer 203. In this case, the scan line SL may include the same material as at least one of the first gate electrode GE1 and the second gate electrode GE2. According to another embodiment, the scan line SL may be disposed between the gate insulating layer 203 and the interlayer insulating layer 206. In this case, the scan line SL may include the same material as at least one of the first upper electrode CE2 and the second upper electrode CE4.

The first source electrode SE1, the first drain electrode DE1, the second source electrode SE2, and the second drain electrode DE2 may be located on the interlayer insulating layer 206. The first source electrode SE1 and the first drain electrode DE1 may each be connected to the first semiconductor layer Act1 via respective contact holes of the first insulating layer 202, the gate insulating layer 203, and the interlayer insulating layer 206. The second source electrode SE2 and the second drain electrode DE2 may each be connected to the second semiconductor layer Act2 via the respective contact holes of the first insulating layer 202, the gate insulating layer 203, and the interlayer insulating layer 206.

The first source electrode SE1, the first drain electrode DE1, the second source electrode SE2, and the second drain electrode DE2 may include a highly conductive material. At least one of the first source electrode SE1, the first drain electrode DE1, the second source electrode SE2, and the second drain electrode DE2 may include a conductive material including Mo, Al, Cu, Ti, etc., and may have a multi-layer or single-layer structure including the aforementioned materials. According to an embodiment, at least one of the first source electrode SE1, the first drain electrode DE1, the second source electrode SE2, and the second drain electrode DE2 may have a multi-layer structure of Ti/Al/Ti.

The first organic insulating layer OIL1 and the second organic insulating layer OIL2 may cover the first source electrode SE1, the first drain electrode DE1, the second source electrode SE2, and the second drain electrode DE2. The first organic insulating layer OIL1 and the second organic insulating layer OIL2 may include an organic material. For example, at least one of the first organic insulating layer OIL1 and the second organic insulating layer OIL2 may include an organic insulating material, such as a commercial polymer such as polymethyl methacrylate (PMMA) or polystyrene (PS)), a polymer derivative having a phenol-based group, an acrylic polymer, an imide-based polymer, an acryl ether-based polymer, an amide-based polymer, a fluorine-based polymer, a p-xylene-based polymer, a vinyl alcohol-based polymer, or a blend thereof.

According to another embodiment, the first connection electrode CM1 and the second connection electrode CM2 may be disposed between the first organic insulating layer OIL1 and the second organic insulating layer OIL2. The first connection electrode CM1 may be connected to the first source electrode SE1 or the first drain electrode DE1 through a contact hole of the first organic insulating layer OIL1. The second connection electrode CM2 may be connected to the second source electrode SE2 or the second drain electrode DE2 through a contact hole of the first organic insulating layer OIL1.

At least one of the first connection electrode CM1 and the second connection electrode CM2 may include a highly conductive material. At least one of the first connection electrode CM1 and the second connection electrode CM2 may include a conductive material including, for example, molybdenum (Mo), aluminum (Al), copper (Cu), titanium (Ti), etc. and may have a multi-layer or single-layer structure including the aforementioned materials. According to an embodiment, at least one of the first connection electrode CM1 and the second connection electrode CM2 may have a multi-layer structure of Ti/Al/Ti. According to some embodiments, the second organic insulating layer OIL2, the first connection electrode CM1, and the second connection electrode CM2 may be omitted.

Although not shown in FIG. 6, the first data line DL1 may be connected to the first pixel circuit PC1. The second data line DL2 may be connected to the second pixel circuit PC2. In this case, the first pixel circuit PC1 and the second pixel circuit PC2 may operate independently.

According to an embodiment, the first data line DL1 and the second data line DL2 may be disposed on the same layer. For example, the first data line DL1 and the second data line DL2 may be disposed between the interlayer insulating layer 206 and the first organic insulating layer OIL1. As another example, the first data line DL1 and the second data line DL2 may be between the first organic insulating layer OIL1 and the second organic insulating layer OIL2. According to another embodiment, the first data line DL1 and the second data line DL2 may be disposed on different layers. For example, one of the first data line DL1 and the second data line DL2 may be disposed between the interlayer insulating layer 206 and the first organic insulating layer OIL1. The other of the first data line DL1 and the second data line DL2 may be disposed between the first organic insulating layer OIL1 and the second organic insulating layer OIL2.

At least one of the first data line DL1 and the second data line DL2 may include a highly conductive material. At least one of the first data line DL1 and the second data line DL2 may include a conductive material including, for example, molybdenum (Mo), aluminum (Al), copper (Cu), titanium (Ti), etc. and may have a multi-layer or single-layer structure including the aforementioned materials. According to an embodiment, at least one of the first data line DL1 and the second data line DL2 may have a multi-layer structure of Ti/Al/Ti.

The display element layer 300 may be located on the pixel circuit layer 200. The display element layer 300 may include a first organic light-emitting diode OLED1 as a first display element, a second organic light-emitting diode OLED2 as a second display element, and a pixel defining layer 320. The first organic light-emitting diode OLED1 may overlap the first area AR1. The first organic light-emitting diode OLED1 may be connected to the first connection electrode CM1 via a contact hole of the second organic insulating layer OIL2, and the first organic light-emitting diode OLED1 may be connected to the first pixel circuit PC1 via the first connection electrode CM1. According to an embodiment, the first organic light-emitting diode OLED1 may overlap the first pixel circuit PC1. The first organic light-emitting diode OLED1 may include a first pixel electrode 311A, a first emission layer 312A, and a first opposite electrode 313A.

The second organic light-emitting diode OLED2 may overlap the second area AR2. The second organic light-emitting diode OLED2 may be connected to the second connection electrode CM2 via a contact hole of the second organic insulating layer OIL2, and the second organic light-emitting diode OLED2 may be connected to the second pixel circuit PC2 via the second connection electrode CM2. The second organic light-emitting diode OLED2 may include a second pixel electrode 311B, a second emission layer 312B, and a second opposite electrode 313B.

The first pixel electrode 311A and the second pixel electrode 311B may be located on the second organic insulating layer OIL2. At least one of the first pixel electrode 311A and the second pixel electrode 311B may include a transparent conductive oxide. According to an embodiment, at least one of the first pixel electrode 311A and the second pixel electrode 311B may include at least one of indium (In), tin (Sn), and oxygen (O). According to an embodiment, at least one of the first pixel electrode 311A and the second pixel electrode 311B may include conductive oxide such as indium tin oxide (ITO), indium zinc oxide (IZO), zinc oxide (ZnO), indium oxide (In₂O₃), indium gallium oxide (IGO), or aluminum zinc oxide (AZO).

The pixel defining layer 320 may include an opening 320OP exposing at least a portion of each of the first pixel electrode 311A and the second pixel electrode 311B. According to an embodiment, the opening 320OP may expose at least a portion of the first pixel electrode 311A and at least a portion of the second pixel electrode 311B. According to another embodiment, a plurality of openings 320OP may be included, and one of the plurality of openings 320OP may expose the first pixel electrode 311A and the other of the plurality of openings 320OP may expose the second pixel electrode 311B. A case where one opening 320OP exposes the first pixel electrode 311A and the second pixel electrode 311B will now be focused on and described in detail.

The pixel defining layer 320 may include an organic insulating material. According to another embodiment, the pixel defining layer 320 may include an inorganic insulating material, such as silicon nitride (SiNₓ), silicon oxynitride (SiON), or silicon oxide (SiO₂). According to another embodiment, the pixel defining layer 320 may include an organic insulating material and an inorganic insulating material. According to some embodiments, the pixel defining layer 320 may include a light shielding material, and may have a black color. The light shielding material may include carbon black, carbon nanotubes, resin or paste including a black pigment, metal particles (e.g., nickel, aluminum, molybdenum, and an alloy thereof), metal oxide particles (e.g., chromium oxide), or metal nitride particles (e.g., chromium nitride). When the pixel defining layer 320 includes the light shielding material, external light reflection due to metal structures arranged under the pixel defining layer 320 may be reduced.

The first emission layer 312A may be located on the first pixel electrode 311A, and the second emission layer 312B may be located on the second pixel electrode 311B. According to an embodiment, the first emission layer 312A and the second emission layer 312B may be integrally provided. According to another embodiment, the first emission layer 312A and the second emission layer 312B may be separated from each other. At least one of the first emission layer 312A and the second emission layer 312B may include a high molecular weight material or a low molecular weight material, and may emit red, green, blue, or white light. According to an embodiment, when the first emission layer 312A and the second emission layer 312B are integrally provided, the first emission layer 312A and the second emission layer 312B may emit light of the same color.

At least one of the first emission layer 312A and the second emission layer 312B may include various organic materials including copper phthalocyanine (CuPc), N,N′-Di(naphthalene-1-yl)-N,N′-diphenyl-benzidine (NPB), and tris-8-hydroxyquinoline aluminum (Alq3).

The first opposite electrode 313A may be located on the first emission layer 312A. The second opposite electrode 313B may be located on the second emission layer 312B. According to an embodiment, the first opposite electrode 313A and the second opposite electrode 313B may be integrally provided. In other words, each of the first opposite electrode 313A and the second opposite electrode 313B may be a portion of the opposite electrode 313.

The opposite electrode 313 may include a conductive material having a low work function. For example, the opposite electrode 313 may include a (semi)transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. Alternatively, the opposite electrode 313 may further include a layer, such as ITO, IZO, ZnO, or In₂O₃, on the (semi)transparent layer including any of the above-described materials.

According to some embodiments, a hole injection layer (HIL) and/or a hole transport layer (HTL) may be between the first pixel electrode 311A and the first emission layer 312A. According to some embodiments, an electron transport layer (ETL) and/or an electron injection layer (EIL) may be disposed between the first emission layer 312A and the opposite electrode 313.

According to some embodiments, an encapsulation layer covering the first organic light-emitting diode OLED1 and the second organic light-emitting diode OLED2 may be located on the display element layer 300.

The first reflective layer 400 may be disposed between the pixel circuit layer 200 and the display element layer 300. According to an embodiment, the first reflective layer 400 may be disposed between the pixel circuit layer 200 and the first pixel electrode 311A. The first reflective layer 400 may overlap the first organic light-emitting diode OLED1 as the first display element. According to an embodiment, an area where the first organic light-emitting diode OLED1 and the first reflective layer 400 overlap each other may be defined as an emission area of the first organic light-emitting diode OLED1.

The first reflective layer 400 may include a reflection film. The first reflective layer 400 may include silver (Ag), magnesium (Mg), aluminum (Al), platinum (Pt), palladium (Pd), gold (Au), nickel (Ni), neodymium (Nd), iridium (Ir), chromium (Cr), or a compound of these materials. Accordingly, the first organic light-emitting diode OLED1 may emit light in a z direction of FIG. 6 so that the first display area DA1 of the display panel 10 displays an image.

The second reflective layer 500 may be located on the display element layer 300. According to an embodiment, the second reflective layer 500 may be located on the opposite electrode 313. The second reflective layer 500 may overlap the second organic light-emitting diode OLED2 as the second display element. The second reflective layer 500 may include a reflection film. According to an embodiment, an area where the second organic light-emitting diode OLED2 and the second reflective layer 500 overlap each other may be defined as an emission area of the second organic light-emitting diode OLED2.

The second reflective layer 500 may include a reflection film. The second reflective layer 500 may include silver (Ag), magnesium (Mg), aluminum (Al), platinum (Pt), palladium (Pd), gold (Au), nickel (Ni), neodymium (Nd), iridium (Ir), chromium (Cr), or a compound of these materials. Accordingly, the second organic light-emitting diode OLED2 may emit light in a −z direction of FIG. 6 so that the second display area DA2 of the display panel 10 displays an image.

The second pixel circuit PC2 may not overlap the second organic light-emitting diode OLED2. Accordingly, when the second organic light-emitting diode OLED2 emits light in the −z direction so that the second display area DA2 of the display panel 10 displays an image, the second pixel circuit PC2 may not reduce the transmittance of the light.

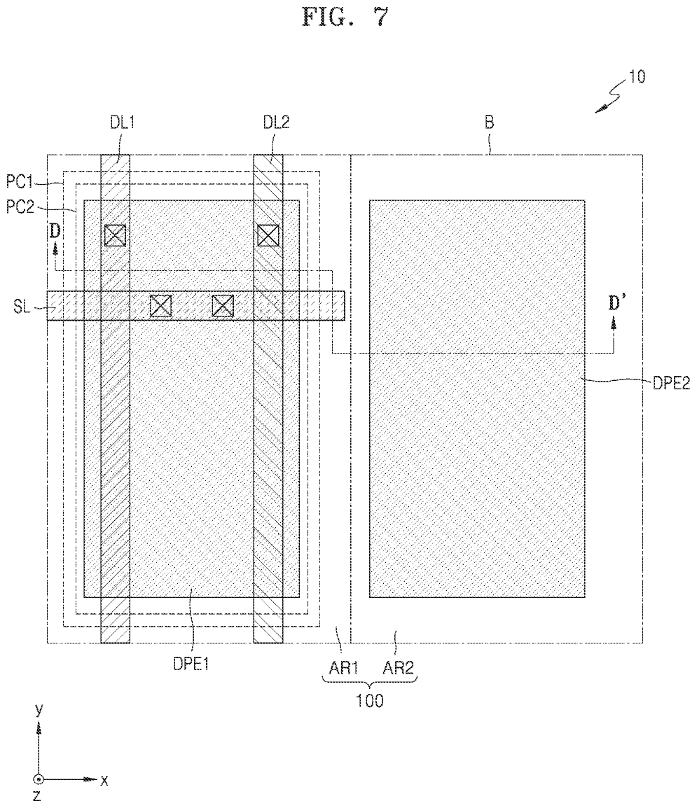

FIG. 7 is an enlarged view of a portion B of the display panel 10 of FIG. 1A, according to another embodiment. Reference numerals in FIG. 7 that are the same as the reference numerals in FIG. 5 denote the same elements, and thus repeated descriptions thereof are omitted.

Referring to FIG. 7, the display panel 10 may display an image. The display panel 10 may include a substrate 100, a first pixel circuit PC1, a second pixel circuit PC2, a scan line SL, a first data line DL1, a second data line DL2, a first display element DPE1, and a second display element DPE2. The substrate 100 may include the first area AR1 and the second area AR2. The first area AR1 and the second area AR2 may be disposed adjacent to each other.

The first pixel circuit PC1 and the second pixel circuit PC2 may be arranged on the substrate 100. According to an embodiment, the first pixel circuit PC1 may overlap the first area AR1. According to an embodiment, the second pixel circuit PC2 may overlap at least one of the first area AR1 and the second area AR2. For example, the second pixel circuit PC2 may overlap the first area AR1. According to an embodiment, the first pixel circuit PC1 and the second pixel circuit PC2 may overlap each other. According to an embodiment, the first pixel circuit PC1 may include a plurality of first thin-film transistors, and the second pixel circuit PC2 may include a plurality of second thin-film transistors. According to an embodiment, the number of first thin-film transistors in the first pixel circuit PC1 may be greater than the number of second thin-film transistors in the second pixel circuit PC2. Accordingly, the area of the second pixel circuit PC2 may be less than that of the first pixel circuit PC1.

The first data line DL1 may overlap the first area AR1. The first data line DL1 may extend in a y direction of FIG. 7. The first data line DL1 may be connected to the first pixel circuit PC1. According to an embodiment, the first data line DL1 may transmit a first data signal to the first pixel circuit PC1.

The second data line DL2 may overlap at least one of the first area AR1 and the second area AR2. For example, the second data line DL2 may overlap the first area AR1. The second data line DL2 may overlap the second pixel circuit PC2. The second data line DL2 may extend in the y direction of FIG. 7. The second data line DL2 may be connected to the second pixel circuit PC2. According to an embodiment, the second data line DL2 may transmit a second data signal to the second pixel circuit PC2. Accordingly, the first pixel circuit PC1 and the second pixel circuit PC2 may operate independently.

According to an embodiment, the first data line DL1 and the second data line DL2 may be disposed on different layers. According to another embodiment, the first data line DL1 and the second data line DL2 may be disposed on the same layer.

Although not shown in FIG. 7, the first display element DPE1 may be connected to the first pixel circuit PC1 and the second display element DPE2 may be connected to the second pixel circuit PC2. According to an embodiment, the first display element DPE1 may overlap the first area AR1. The second display element DPE2 may overlap the second area AR2.

The first display element DPE1 may emit light in a z direction of FIG. 7 so that the first display area DA1 (see FIG. 1A) of the display panel 10 displays an image. The second display element DPE2 may not overlap the second pixel circuit PC2. Accordingly, the second display element DPE2 may emit light in a −z direction of FIG. 7 so that the second display area DA2 (see FIG. 1B) of the display panel 10 displays an image.

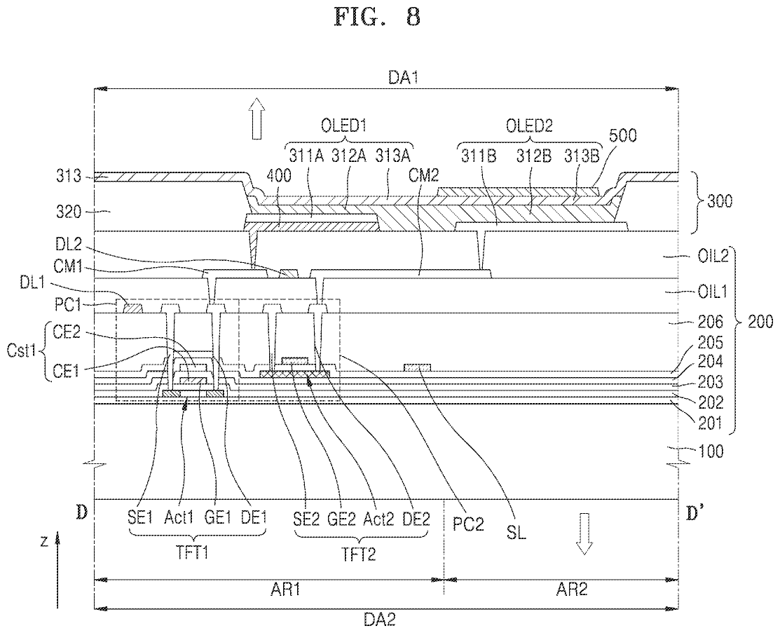

FIG. 8 is a cross-sectional view of the display panel 10 of FIG. 7 taken along line D-D′ of FIG. 7. Reference numerals in FIG. 8 that are the same as the reference numerals in FIG. 7 denote the same elements, and thus repeated descriptions thereof are omitted.

Referring to FIG. 8, the display panel 10 may include a first surface including the first display area DA1 and a second surface including the second display area DA2. The first display area DA1 may display an image in a z direction of FIG. 8. The second display area DA2 may display an image in a −z direction of FIG. 8. The display panel 10 may include the substrate 100, a pixel circuit layer 200, a display element layer 300, a first reflective layer 400, and a second reflective layer 500. The substrate 100 may include the first area AR1 and the second area AR2. The first area AR1 and the second area AR2 may be disposed adjacent to each other.

The pixel circuit layer 200 may be located on the substrate 100. The pixel circuit layer 200 may include the first pixel circuit PC1, the second pixel circuit PC2, the scan line SL, the first data line DL1, the second data line DL2, a first connection electrode CM1, a second connection electrode CM2, a buffer layer 201, a first insulating layer 202, a gate insulating layer 203, an intermediate insulating layer 204, a second insulating layer 205, an interlayer insulating layer 206, a first organic insulating layer OIL1, and a second organic insulating layer OIL2.

The first pixel circuit PC1 may be located in the first area AR1. The first pixel circuit PC1 may include a first thin-film transistor TFT1 and a first storage capacitor Cst1. The first thin-film transistor TFT1 may include a first semiconductor layer Act1, a first gate electrode GE1, a first source electrode SE1, and a first drain electrode DEL The first storage capacitor Cst1 may include a first lower electrode CE1 and a first upper electrode CE2. According to an embodiment, the first pixel circuit PC1 may include a plurality of first thin-film transistors TFT1.

The second pixel circuit PC2 may be located in at least one of the first area AR1 and the second area AR2. For example, the second pixel circuit PC2 may be located in the first area AR1. According to an embodiment, the second pixel circuit PC2 and the first pixel circuit PC1 may overlap each other in a plan view. According to an embodiment, the second pixel circuit PC2 and the first pixel circuit PC1 may not overlap each other in a plan view. The second pixel circuit PC2 may include a second thin-film transistor TFT2. The second thin-film transistor TFT2 may include a second semiconductor layer Act2, a second gate electrode GE2, a second source electrode SE2, and a second drain electrode DE2. According to an embodiment, the second pixel circuit PC2 may include a plurality of second thin-film transistors TFT2. Although not shown in FIG. 8, the number of first thin-film transistors TFT1 in the first pixel circuit PC1 may be greater than the number of second thin-film transistors TFT2 in the second pixel circuit PC2.

The buffer layer 201 may be located on the substrate 100. The first semiconductor layer Act1 may be located on the substrate 100. According to an embodiment, the first semiconductor layer Act1 may be located on the buffer layer 201. The first semiconductor layer Act1 may be a first semiconductor layer Act1 of one of the plurality of first thin-film transistors TFT1. The first insulating layer 202 may cover the first semiconductor layer Act1. The first gate electrode GE1 may be located on the first insulating layer 202. The gate insulating layer 203 may cover the first gate electrode GE1. The first upper electrode CE2 may be located on the gate insulating layer 203.

The intermediate insulating layer 204 may cover the first upper electrode CE2. The intermediate insulating layer 204 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO), or the like. The intermediate insulating layer 204 may be a single layer or multi-layer including the aforementioned inorganic insulating materials.

The second semiconductor layer Act2 may be located on the intermediate insulating layer 204. According to an embodiment, the second semiconductor layer Act2 may be located on the first insulating layer 202. The second semiconductor layer Act2 may include an oxide semiconductor. The second semiconductor layer Act2 may include Zn oxide, In—Zn oxide, Ga—In—Zn oxide, or the like as a Zn oxide-based material. Alternatively, the second semiconductor layer Act2 may include an In—Ga—Zn—O (IGZO), In—Sn—Zn—O (ITZO), or In—Ga—Sn—Zn—O (IGTZO) semiconductor containing a metal, such as In, Ga, or Sn, in ZnO.

The second semiconductor layer Act2 may include a channel region, and a source region and a drain region respectively arranged on both sides of the channel region. The source region and the drain region of the second semiconductor layer Act2 may be formed by making an oxide semiconductor be conductive by controlling the carrier concentration of an oxide semiconductor. For example, the source region and the drain region of the second semiconductor layer Act2 may be formed by increasing the carrier concentration of an oxide semiconductor by performing plasma processing on the oxide semiconductor by using a hydrogen (H)-based gas, a fluorine (F)-based gas, or a combination thereof.

The second insulating layer 205 may cover the second semiconductor layer Act2. The second insulating layer 205 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO), or the like. The second insulating layer 205 may be a single layer or multi-layer including the aforementioned inorganic insulating materials.

The second gate electrode GE2 may be located on the second insulating layer 205. The second gate electrode GE2 may overlap the second semiconductor layer Act2. The interlayer insulating layer 206 may cover the second gate electrode GE2.

Although not shown in FIG. 8, the scan line SL may be connected to each of the first pixel circuit PC1 and the second pixel circuit PC2. The scan line SL may be located on the first insulating layer 202. According to an embodiment, the scan line SL may be disposed between the first insulating layer 202 and the gate insulating layer 203. In this case, the scan line SL may include the same material as the first gate electrode GE1. According to another embodiment, the scan line SL may be disposed between the gate insulating layer 203 and the intermediate insulating layer 204. In this case, the scan line SL may include the same material as the first upper electrode CE2. According to another embodiment, the scan line SL may be disposed between the second insulating layer 205 and the interlayer insulating layer 206. In this case, the scan line SL may include the same material as the second gate electrode GE2.

The first source electrode SE1, the first drain electrode DE1, the second source electrode SE2, and the second drain electrode DE2 may be located on the interlayer insulating layer 206. The first source electrode SE1 and the first drain electrode DE1 may each be connected to the first semiconductor layer Act1 via respective contact holes of the first insulating layer 202, the gate insulating layer 203, the intermediate insulating layer 204, the second insulating layer 205, and the interlayer insulating layer 206. The second source electrode SE2 and the second drain electrode DE2 may each be connected to the second semiconductor layer Act2 via the respective contact holes of the second insulating layer 205 and the interlayer insulating layer 206.

Although not shown in FIG. 8, the first data line DL1 may be connected to the first pixel circuit PC1. The second data line DL2 may be connected to the second pixel circuit PC2. In this case, the first pixel circuit PC1 and the second pixel circuit PC2 may operate independently.

According to an embodiment, the first data line DL1 and the second data line DL2 may be disposed on the same layer. For example, the first data line DL1 and the second data line DL2 may be disposed between the interlayer insulating layer 206 and the first organic insulating layer OIL1. As another example, the first data line DL1 and the second data line DL2 may be disposed between the first organic insulating layer OIL1 and the second organic insulating layer OIL2. According to another embodiment, the first data line DL1 and the second data line DL2 may be disposed on different layers. One of the first data line DL1 and the second data line DL2 may be disposed between the interlayer insulating layer 206 and the first organic insulating layer OIL1. The other of the first data line DL1 and the second data line DL2 may be disposed between the first organic insulating layer OIL1 and the second organic insulating layer OIL2. For example, the first data line DL1 may be disposed between the interlayer insulating layer 206 and the first organic insulating layer OIL1. The second data line DL2 may be disposed between the first organic insulating layer OIL1 and the second organic insulating layer OIL2.

According to the present embodiment, the first semiconductor layer Act1 may be disposed between the substrate 100 and the first insulating layer 202, and the second semiconductor layer Act2 may be between the intermediate insulating layer 204 and the second insulating layer 205. Accordingly, the first pixel circuit PC1 and the second pixel circuit PC2 may overlap each other and may be located in the first area AR1. In this case, because the second pixel circuit PC2 does not overlap the second area AR2, an area through which the second organic light-emitting diode OLED2 emits light in the −z direction may be increased.

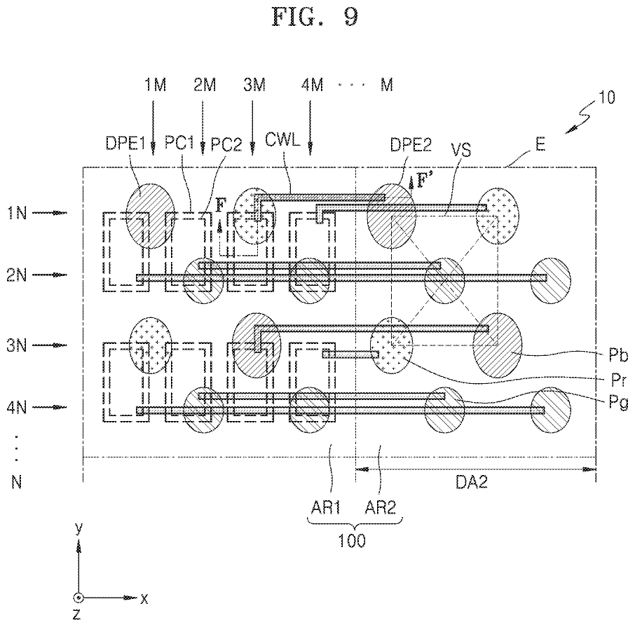

FIG. 9 is an enlarged view of a portion E of the display panel 10 of FIG. 1A, according to an embodiment.

Referring to FIG. 9, the display panel 10 may include the substrate 100, the first pixel circuit PC1, the second pixel circuit PC2, the first display element DPE1, the second display element DPE2, and a connection line CWL.

The substrate 100 may include the first area AR1 and the second area AR2. The first area AR1 and the second area AR2 may be disposed adjacent to each other. According to an embodiment, the second area AR2 may overlap the second display area DA2 of the display panel 10. The first area AR1 may be an area that does not overlap the second display area DA2 of the display panel 10. According to an embodiment, in a plan view, the first area AR1 may be located around the second display area DA2 of the display panel 10.

The first pixel circuit PC1 and the second pixel circuit PC2 may be located on the substrate 100. Each of the first pixel circuit PC1 and the second pixel circuit PC2 may overlap the first area AR1. According to an embodiment, the first pixel circuit PC1 and the second pixel circuit PC2 may overlap each other. According to another embodiment, the first pixel circuit PC1 and the second pixel circuit PC2 may not overlap each other.

The first display element DPE1 and the second display element DPE2 may be located on the substrate 100. The first display element DPE1 may be connected to the first pixel circuit PC1 and the second display element DPE2 may be connected to the second pixel circuit PC2. According to an embodiment, the first display element DPE1 may overlap the first area AR1. The second display element DPE2 may overlap the second area AR2.

According to an embodiment, at least one of the first display element DPE1 and the second display element DPE2 may be implemented as a red subpixel Pr, a green subpixel Pg, or a blue subpixel Pb. A subpixel, as used herein, refers to a light-emission area as a minimum unit that realizes an image.

A red subpixel Pr, a green subpixel Pg, and a blue subpixel Pb may be arranged in a PenTile structure. A plurality of red subpixels Pr and a plurality of blue subpixels Pb may be arranged alternately on a first row 1N. A plurality of green subpixels Pg may be arranged to be spaced apart from one another at regular intervals on a second row 2N adjacent to the first row 1N. A plurality of red subpixels Pr and a plurality of blue subpixels Pb may be arranged alternately on a third row 3N adjacent to the second row 2N. A plurality of green subpixels Pg may be arranged to be spaced apart from one another at regular intervals on a fourth row 4N adjacent to the third row 3N. This subpixel arrangement may be repeated up to an N-th row. According to an embodiment, the red subpixels Pr and the blue subpixels Pb may be larger than the green subpixels Pg. In FIG. 9, each of the red subpixels Pr, the blue subpixels Pb, and the green subpixels Pg has an oval shape. However, according to another embodiment, each of the red subpixels Pr, the blue subpixels Pb, and the green subpixels Pg may have a polygonal shape or a circular shape.

The plurality of red subpixels Pr and the plurality of blue subpixels Pb disposed on the first row 1N, and the plurality of green subpixels Pg disposed on the second row 2N may be arranged in a zigzag configuration. Accordingly, a plurality of red subpixels Pr and a plurality of blue subpixels Pb may be arranged alternately on a first column 1M. A plurality of green subpixels Pg may be arranged to be spaced apart from one another at regular intervals on a second column 2M disposed adjacent to the first column 1M. A plurality of red subpixels Pr and a plurality of blue subpixels Pb may be arranged alternately on a third column 3M disposed adjacent to the second column 2M. A plurality of green subpixels Pg may be arranged spaced apart from one another at regular intervals on a fourth column 4M disposed adjacent to the third column 3M. This subpixel arrangement may be repeated up to an M-th column.

Describing this subpixel arrangement structure differently, a green subpixel Pg may be arranged at the center of the virtual quadrilateral VS. According to an embodiment, a center point of the green subpixel Pg may be a center point of the virtual quadrilateral VS. A red subpixel Pr and a blue subpixel Pb may be arranged at vertexes of the virtual quadrilateral VS, respectively. According to an embodiment, red subpixels Pr may be arranged at a first vertex and a third vertex facing each other from among the vertexes of the virtual quadrilateral VS, respectively. According to an embodiment, blue subpixels Pb may be arranged at a second vertex and a fourth vertex facing each other from among the vertexes of the virtual quadrilateral VS, respectively. The virtual quadrilateral VS may be a rectangle, a rhombus, a square, or the like.

This pixel arrangement structure may be referred to as a PENTILE™ matrix structure or a PenTile structure. By applying rendering, in which a color of a subpixel is represented by sharing the colors of its adjacent subpixels, a high resolution may be obtained via a small number of subpixels.

The connection line CWL may extend from the first area AR1 to the second area AR2. The connection line CWL may overlap the first area AR1 and the second area AR2. The connection line CWL may connect the second pixel circuit PC2 to the second display element DPE2. Accordingly, no second pixel circuits PC2 may be arranged in the second area AR2, and the light transmittance of the display panel 10 may increase in the second area AR2.

The connection line CWL may include a transparent conductive oxide. For example, the connection line CWL may include conductive oxide such as indium tin oxide (ITO), indium zinc oxide (IZO), zinc oxide (ZnO), indium oxide (In₂O₃), indium gallium oxide (IGO), or aluminum zinc oxide (AZO). Accordingly, even when the connection line CWL is arranged in the second area AR2, the display panel 10 may maintain a high light transmittance.

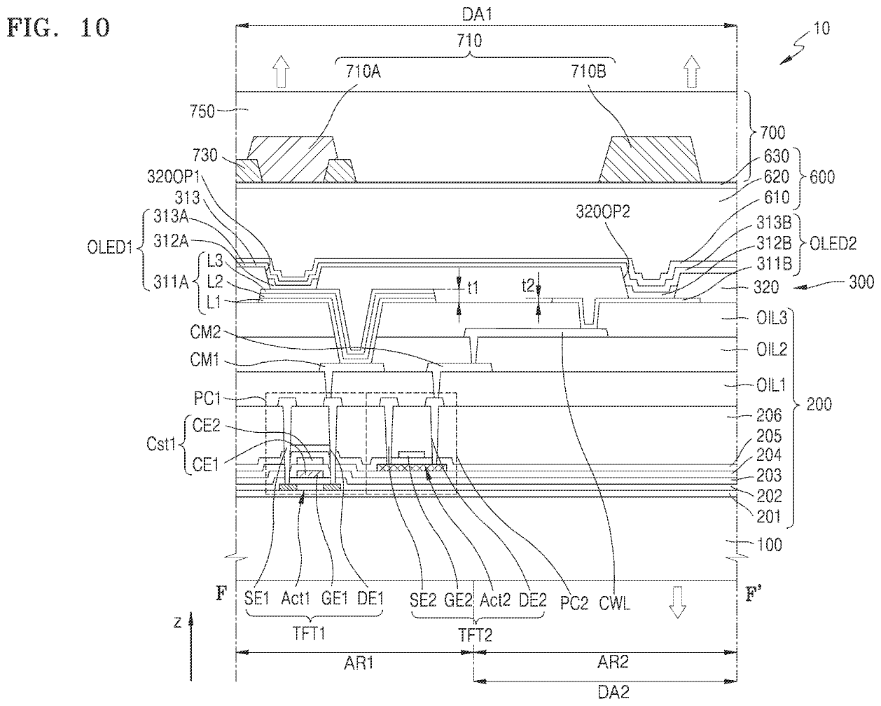

FIG. 10 is a cross-sectional view of the display panel 10 of FIG. 9 taken along line F-F′ of FIG. 9. Reference numerals in FIG. 10 that are the same as the reference numerals in FIG. 8 denote the same elements, and thus repeated descriptions thereof are omitted.

Referring to FIG. 10, the display panel 10 may include a first surface including the first display area DA1 and a second surface including the second display area DA2. The first display area DA1 may display an image in a z direction of FIG. 10. The second display area DA2 may display an image in a −z direction of FIG. 10. The display panel 10 may include the substrate 100, a pixel circuit layer 200, a display element layer 300, an encapsulation layer 600, and an anti-reflective layer 700.

The substrate 100 may include the first area AR1 and the second area AR2. The first area AR1 and the second area AR2 may be disposed adjacent to each other. According to an embodiment, the second area AR2 may overlap the second display area DA2 of the display panel 10. The first area AR1 may be an area that does not overlap the second display area DA2 of the display panel 10.

The pixel circuit layer 200 may be located on the substrate 100. The pixel circuit layer 200 may include the first pixel circuit PC1, the second pixel circuit PC2, the first connection electrode CM1, the second connection electrode CM2, the buffer layer 201, the first insulating layer 202, the gate insulating layer 203, the intermediate insulating layer 204, the second insulating layer 205, the interlayer insulating layer 206, the first organic insulating layer OIL1, the second organic insulating layer OIL2, the connection line CWL, and a third organic insulating layer OIL3.

The first pixel circuit PC1 may be located in the first area AR1. The first pixel circuit PC1 may include a first thin-film transistor TFT1 and a first storage capacitor Cst1. The first thin-film transistor TFT1 may include a first semiconductor layer Act1, a first gate electrode GE1, a first source electrode SE1, and a first drain electrode DEL The first storage capacitor Cst1 may include a first lower electrode CE1 and a first upper electrode CE2. According to an embodiment, the first pixel circuit PC1 may include a plurality of first thin-film transistors TFT1.

The second pixel circuit PC2 may be located in the first area AR1. According to an embodiment, the second pixel circuit PC2 and the first pixel circuit PC1 may overlap each other. According to another embodiment, the second pixel circuit PC2 and the first pixel circuit PC1 may not overlap each other. The second pixel circuit PC2 may include a second thin-film transistor TFT2. The second thin-film transistor TFT2 may include a second semiconductor layer Act2, a second gate electrode GE2, a second source electrode SE2, and a second drain electrode DE2. According to an embodiment, the second pixel circuit PC2 may include a plurality of second thin-film transistors TFT2. Although not shown in FIG. 10, the number of first thin-film transistors TFT1 in the first pixel circuit PC1 may be greater than the number of second thin-film transistors TFT2 in the second pixel circuit PC2. According to another embodiment, the number of first thin-film transistors TFT1 in the first pixel circuit PC1 may be equal to the number of second thin-film transistors TFT2 in the second pixel circuit PC2.

The connection line CWL may extend from the first area AR1 to the second area AR2. The connection line CWL may overlap the first area AR1 and the second area AR2. The connection line CWL may connect the second pixel circuit PC2 to the second display element DPE2. Accordingly, no second pixel circuits PC2 may be arranged in the second area AR2, and the light transmittance of the display panel 10 may increase in the second area AR2.

According to an embodiment, the connection line CWL may be disposed between the second organic insulating layer OIL2 and the third organic insulating layer OIL3. In this case, the connection line CWL may be connected to the second connection electrode CM2 through a contact hole of the second organic insulating layer OIL2. According to another embodiment, the connection line CWL may be disposed between the interlayer insulating layer 206 and the first organic insulating layer OIL1.

The display element layer 300 may be located on the pixel circuit layer 200. The display element layer 300 may include a first organic light-emitting diode OLED1 as a first display element, a second organic light-emitting diode OLED2 as a second display element, and a pixel defining layer 320.

The first organic light-emitting diode OLED1 may overlap the first area AR1. The first organic light-emitting diode OLED1 may be connected to the first connection electrode CM1 via a contact hole of the second organic insulating layer OIL2 and a contact hole of the third organic insulating layer OIL3, and the first organic light-emitting diode OLED1 may be connected to the first pixel circuit PC1 via the first connection electrode CM1. According to an embodiment, the first organic light-emitting diode OLED1 may overlap the first pixel circuit PC1. The first organic light-emitting diode OLED1 may include a first pixel electrode 311A, a first emission layer 312A, and a first opposite electrode 313A.

The first pixel electrode 311A may have a first thickness t1. The first thickness t1 may be a distance between a lower surface of the first pixel electrode 311A facing the substrate 100 and an upper surface of the first pixel electrode 311A opposite to the lower surface of the first pixel electrode 311A.

The first pixel electrode 311A may be a stack of a plurality of layers. According to an embodiment, the first pixel electrode 311A may include a first layer L1, a second layer L2, and a third layer L3.

The first layer L1 may include transparent conductive oxide. According to an embodiment, the first layer L1 may include at least one of indium (In), tin (Sn), and oxygen (O). According to an embodiment, the first layer L1 may include conductive oxide such as indium tin oxide (ITO), indium zinc oxide (IZO), zinc oxide (ZnO), indium oxide (In₂O₃), indium gallium oxide (IGO), or aluminum zinc oxide (AZO).

The second layer L2 may include a reflection film. The second layer L2 may be located on the first layer L1. According to another embodiment, the second layer L2 may include silver (Ag), magnesium (Mg), aluminum (Al), platinum (Pt), palladium (Pd), gold (Au), nickel (Ni), neodymium (Nd), iridium (Ir), chromium (Cr), or a compound of these materials.

The third layer L3 may include transparent conductive oxide. The third layer L3 may be located on the second layer L2. According to an embodiment, the third layer L3 may include at least one of indium (In), tin (Sn), and oxygen (O). According to an embodiment, the third layer L3 may include conductive oxide such as indium tin oxide (ITO), indium zinc oxide (IZO), zinc oxide (ZnO), indium oxide (In₂O₃), indium gallium oxide (IGO), or aluminum zinc oxide (AZO).

The second organic light-emitting diode OLED2 may overlap the second area AR2. The second organic light-emitting diode OLED2 may be connected to the connection line CWL via a contact hole of the third organic insulating layer OIL3, and the second organic light-emitting diode OLED2 may be connected to the second pixel circuit PC2 via the connection line CWL. The second organic light-emitting diode OLED2 may include a second pixel electrode 311B, a second emission layer 312B, and a second opposite electrode 313B.

The second pixel electrode 311B may have a second thickness t2. The second thickness t2 may be a distance between a lower surface of the second pixel electrode 311B facing the substrate 100 and an upper surface of the second pixel electrode 311B opposite to the lower surface of the second pixel electrode 311B. According to an embodiment, the second thickness t2 may be less than the first thickness t1.

The second pixel electrode 311B may include transparent conductive oxide. According to an embodiment, the second pixel electrode 311B may include at least one of indium (In), tin (Sn), and oxygen (O). According to an embodiment, the second pixel electrode 311B may include conductive oxide such as indium tin oxide (ITO), indium zinc oxide (IZO), zinc oxide (ZnO), indium oxide (In₂O₃), indium gallium oxide (IGO), or aluminum zinc oxide (AZO).

A pixel defining layer 320 may cover the edge of each of the first pixel electrode 311A and the second pixel electrode 311B. The pixel defining layer 320 may include a first electrode opening 320OP1 exposing a center portion of the first pixel electrode 311A, and a second electrode opening 320OP2 exposing a center portion of the second pixel electrode 311B. According to an embodiment, an emission area of the first organic light-emitting diode OLED1 may be defined as the area of the first electrode opening 320OP1. The emission area of the second organic light-emitting diode OLED2 may be defined as the area of the second electrode opening 320OP2.

The first emission layer 312A may overlap the first electrode opening 320OP1 and may be located on the first pixel electrode 311A. The second emission layer 312B may overlap the second electrode opening 320OP2 and may be located on the second pixel electrode 311B. The opposite electrode 313 may be located on the first emission layer 312A and the second emission layer 312B.

Because the first pixel electrode 311A includes a reflective film, the first organic light-emitting diode OLED1 may emit light in a z direction of FIG. 10 so that the first display area DA1 of the display panel 10 displays an image.

Because the second pixel electrode 311B includes no reflective films, the second organic light-emitting diode OLED2 may emit light in the z direction of FIG. 10 so that the first display area DA1 of the display panel 10 displays an image, and may emit light in a −z direction of FIG. 10 so that the second display area DA2 of the display panel 10 displays an image. In other words, the second organic light-emitting diode OLED2 may emit light in both directions.

The encapsulation layer 600 may be located on the display element layer 300. The encapsulation layer 600 may protect the display element layer 300. According to an embodiment, the encapsulation layer 600 may include at least one inorganic encapsulation layer and at least one organic encapsulation layer. The at least one inorganic encapsulation layer may include one or more inorganic materials from among aluminum oxide (Al₂O₃), titanium oxide (TiO₂), tantalum oxide (Ta₂O₅), zinc oxide (ZnO), silicon oxide (SiO₂), silicon nitride (SiN_{X}), and silicon oxynitride (SiON). The at least one organic encapsulation layer may include a polymer-based material. Examples of the polymer-based material may include an acrylic resin, an epoxy-based resin, polyimide, and polyethylene. According to an embodiment, the at least one organic encapsulation layer may include acrylate. According to an embodiment, the encapsulation layer 600 may include a first inorganic encapsulation layer 610, an organic encapsulation layer 620, and a second inorganic encapsulation layer 630 sequentially stacked on one another.

According to another embodiment, the encapsulation layer 600 may be obtained by coupling the substrate 100 with a transparent upper substrate and sealing an internal space between the substrate 100 and the transparent upper substrate.

The anti-reflective layer 700 may be located on the encapsulation layer 600. The anti-reflective layer 700 may include a color filter 710, a black matrix 730, and a planarization layer 750. The color filter 710 may overlap the first organic light-emitting diode OLED1 as a first display element and the second organic light-emitting diode OLED2 as a second display element. The color filter 710 may be arranged in consideration of the color of light emitted by the first organic light-emitting diode OLED1 and the second organic light-emitting diode OLED2. The color filter 710 may include a pigment or dye of a red, green, or blue color. Alternatively, the color filter 710 may further include quantum dots in addition to the above-described pigment or dye. Alternatively, the color filter 710 may not include the above-described pigment or dye, and may include scattered particles such as titanium oxide. According to an embodiment, the color filter 710 may include a first color filter 710A and a second color filter 710B. The first color filter 710A may overlap the first organic light-emitting diode OLED1. The second organic light-emitting diode OLED2 may overlap the second color filter 710B.

The black matrix 730 may absorb at least a portion of external light or internal reflected light. The black matrix 730 may include a black pigment. According to an embodiment, the black matrix 730 may overlap the first area AR1 and may be disposed adjacent to the first color filter 710A. According to an embodiment, the black matrix 730 may not overlap the second area AR2 and may not be adjacent to the second color filter 710B. In this case, the light transmittance of the display panel 10 in the second area AR2 may be higher than that of the display panel 10 in the first area AR1. According to another embodiment, the black matrix 730 may not overlap the second area AR2 and may be disposed adjacent to the second color filter 710B.

The planarization layer 750 may be located on the color filter 710 and the black matrix 730. An upper surface of the planarization layer 750 may be flat. According to an embodiment, the planarization layer 750 may include an organic material. For example, the planarization layer 750 may include a polymer-based material. The aforementioned polymer-based material may be transparent. For example, the planarization layer 750 may include silicon-based resin, acrylic resin, epoxy-based resin, polyimide, and polyethylene.

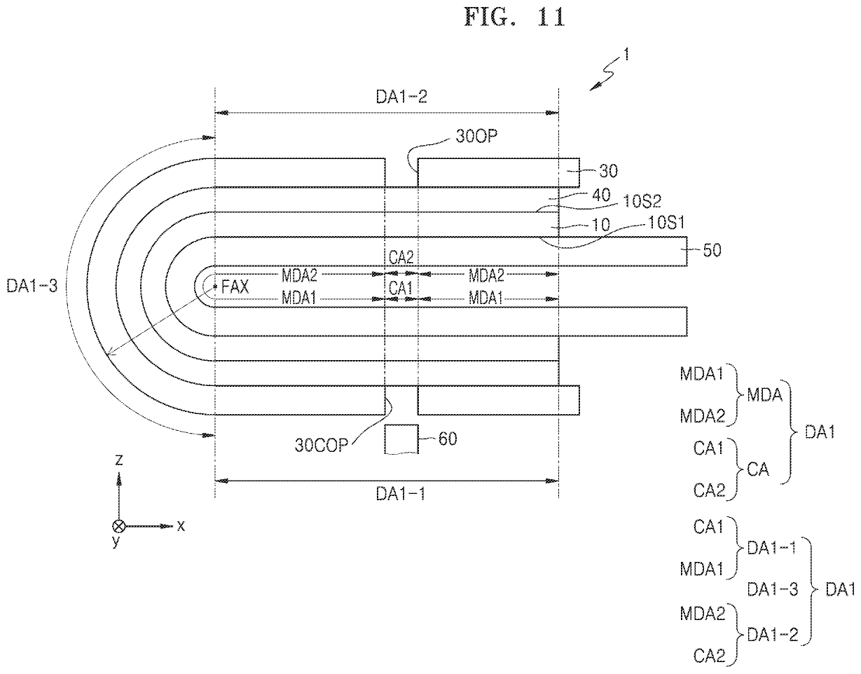

FIG. 11 is a schematic cross-sectional view of a display apparatus 1 according to another embodiment. Reference numerals in FIG. 11 that are the same as the reference numerals in FIG. 3A denote the same elements, and thus repeated descriptions thereof are omitted.

Referring to FIG. 11, the display apparatus 1 may include a display panel 10, a set assembly 30, a cover panel 40, a cover window 50, and a component 60. The display panel 10 may display an image. According to an embodiment, the display panel 10 may include a first surface 10S1 and a second surface 10S2. The first surface 10S1 and the second surface 10S2 may face directions opposite to each other. The first surface 10S1 may include a first display area DA1 displaying an image. The first display area DA1 may include a first portion area DA1-1, a second portion area DA1-2, and a third portion area DA1-3.

The display apparatus 1 may be folded about the folding axis FAX extending across the first surface 10S1. The first portion area DA1-1 and the second portion area DA1-2 of the display panel 10 folded about the folding axis FAX may face each other. According to another embodiment, the first portion area DA1-1 and the second portion area DA1-2 of the display panel 10 folded about the folding axis FAX may face opposite directions.

The first display area DA1 may include a main display area MDA and a component area CA. The main display area MDA may include a first main display area MDA1 overlapping the first portion area DA1-1, and a second main display area MDA2 overlapping the second portion area DA1-2. The component area CA may include a first component area CA1 overlapping the first portion area DA1-1, and a second component area CA2 overlapping the second portion area DA1-2.

The set assembly 30 may be located on the second surface 10S2. The set assembly 30 may support the display panel 10. The set assembly 30 may include an opening 30OP exposing the second surface 10S2. According to an embodiment, the set assembly 30 may include a component opening 30COP overlapping the component 60.

The cover panel 40 may be disposed between the display panel 10 and the set assembly 30. According to an embodiment, the cover panel 40 may continuously extend on the second surface 10S2. Accordingly, even when the set assembly 30 includes the opening 30OP and the component opening 30COP, the cover panel 40 may protect the display panel 10.

The component 60 may overlap the component area CA. The component 60 may be located to overlap the first component area CAL According to an embodiment, when the display apparatus 1 is folded about the folding axis FAX, the component 60 may overlap the first component area CA1 and the second component area CA2. According to an embodiment, when the display apparatus 1 is unfolded, the component 60 may overlap the first component area CA1 and may not overlap the second component area CA2.

The component 60 is a camera using infrared light, visible light, or the like, and may include a photographing device. Alternatively, the component 60 may be a solar battery, a flash, an illuminance sensor, a proximity sensor, or an iris sensor. Alternatively, the component 60 may have a function of receiving sound.

According to an embodiment, when the display apparatus 1 is folded about the folding axis FAX, the component area CA and the opening 30OP may overlap each other. According to an embodiment, when the display apparatus 1 is folded about the folding axis FAX, the component opening 30COP and the opening 30OP may overlap each other. Accordingly, when the display apparatus 1 is folded about the folding axis FAX, the display apparatus 1 may perform an operation of the component 60 via the opening 30OP or may display an image. According to an embodiment, when the display apparatus 1 is unfolded, the component opening 30COP and the opening 30OP may not overlap each other.

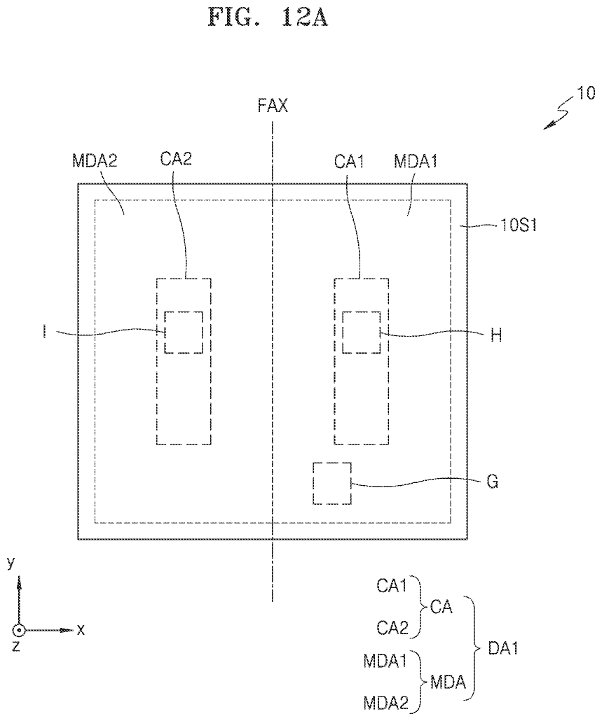

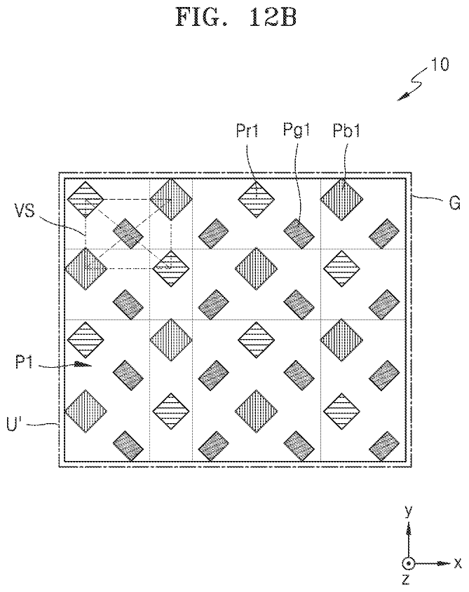

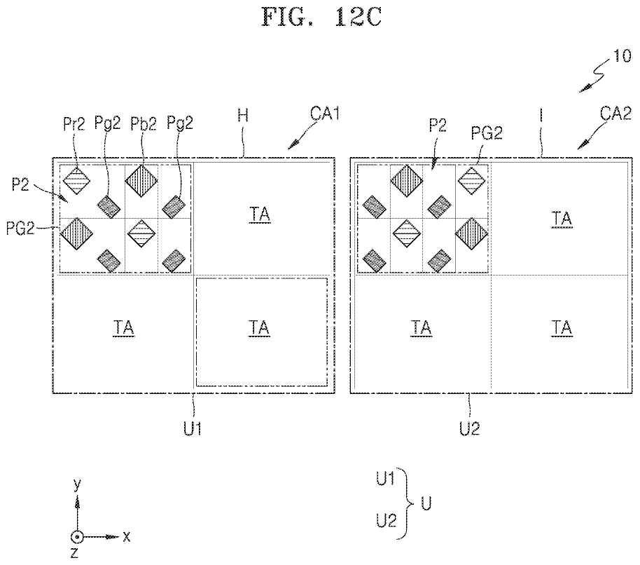

FIG. 12A is a schematic plan view of the display panel 10 included in the display apparatus 1 of FIG. 11. FIG. 12B is an enlarged view of a portion G of the display panel 10 of FIG. 12A. FIG. 12C is an enlarged view of a portion H of the first component area CA1 of the display panel 10 of FIG. 12A and a portion I of the second component area CA2 of the display panel 10 of FIG. 12A. FIG. 12A is a plan view of the display panel 10 in an unfolded state.

Referring to FIG. 12A, the display panel 10 may include a first surface 10S1 including the first display area DA1. The first display area DA1 may include the main display area MDA and the component area CA. The main display area MDA may surround at least a portion of the component area CA. According to an embodiment, the main display area MDA may entirely surround the component area CA. The component area CA may include the first component area CA1 and the second component area CA2.

The display panel 10 may be folded about the folding axis FAX extending across the first surface 10S1. According to an embodiment, the main display area MDA may include the first main display area MDA1 and the second main display area MDA2 located with the folding axis FAX disposed therebetween.

The first component area CA1 and the second component area CA2 may be spaced apart from each other with the folding axis FAX disposed therebetween. The first main display area MDA1 may surround at least a portion of the first component area CAL According to an embodiment, the first main display area MDA1 may entirely surround the first component area CAL The second main display area MDA2 may surround at least a portion of the second component area CA2. According to an embodiment, the second main display area MDA2 may entirely surround the second component area CA2.

Referring to FIG. 12B, the display panel 10 may include a plurality of first subpixels P1 arranged in the main display area MDA. A first subpixel P1 may be implemented as a display element. The area of the first subpixel P1 may include an emission area of the display element. Each of the plurality of first subpixels P1 may emit red light, green light, blue light, or white light. According to an embodiment, the plurality of first subpixels P1 may include a first red subpixel Pr1, a first green subpixel Pg1, and a first blue subpixel Pb1. The plurality of first subpixels P1 may be arranged in a PENTILE™ matrix structure. According to an embodiment, the first green subpixel Pg1 may be located at the center of the virtual quadrilateral VS. According to an embodiment, a center point of the first green subpixel Pg1 may be a center point of the virtual quadrilateral VS. The first red subpixel Pr1 and the first blue subpixel Pb1 may be located at vertexes of the virtual quadrilateral VS, respectively. According to an embodiment, first red subpixels Pr1 may be arranged at a first vertex and a third vertex facing each other from among the vertexes of the virtual quadrilateral VS, respectively. First blue subpixels Pb1 may be arranged at a second vertex and a fourth vertex facing each other from among the vertexes of the virtual quadrilateral VS, respectively. The virtual quadrilateral VS may be a rectangle, a rhombus, a square, or the like.

Referring to FIG. 12C, the display panel 10 may include a plurality of second subpixels P2 arranged in the component area CA. A second subpixel P2 may be implemented as a display element. The area of the second subpixel P2 may include an emission area of the display element. Each of the plurality of second subpixels P2 may emit red light, green light, blue light, or white light. According to an embodiment, the plurality of second subpixels P2 may include a second red subpixel Pr2, a second green subpixel Pg2, and a second blue subpixel Pb2.

The component area CA may include a transmission area TA disposed adjacent to the plurality of second subpixels P2. The plurality of second subpixels P2 and the transmission area TA may be disposed adjacent to each other in an x direction of FIG. 12C and/or a y direction of FIG. 12C.

The plurality of second subpixels P2 may constitute a second pixel group PG2. In other words, the second pixel group PG2 may include a subpixel set in which a plurality of second subpixels P2 are grouped in a predetermined unit. In FIG. 12C, a single second pixel group PG2 may include eight second subpixels P2 arranged in a PenTile structure. In other words, a single second pixel group PG2 may include two second red subpixels Pr2, four second green subpixels Pg2, and two second blue subpixels Pb2.

A basic unit U including a certain number of second pixel groups PG2 and a certain number of transmission areas TA may be disposed in the component area CA. In the component area CA, the basic unit U may be repeated in the x direction of FIG. 12C and/or the y direction of FIG. 12C. In FIG. 12C, the basic unit U may have a quadrilateral shape in which one second pixel group PG2 and three transmission areas TA arranged around the second pixel group PG2 are grouped.

An area disposed in the main display area MDA which corresponds to the basic unit U may be a corresponding unit U′. The number of first subpixels P1 included in the corresponding unit U′ may be greater than that of second subpixels P2 included in the basic unit U. In other words, the number of second subpixels P2 included in the basic unit U is 8 and the number of first subpixels P1 included in the corresponding unit U′ is 32, and thus a ratio of the number of second subpixels P2 disposed in the basic unit U to the number of first subpixels P1 disposed in the corresponding unit U′ may be 1:4.

An arrangement structure of the second subpixels P2 as shown in FIG. 12C may be a PenTile structure, and may have a resolution that is ¼ the resolution of the main display area MDA. This PenTile structure may be understood as a ¼ PenTile structure. However, embodiments are not limited thereto, and the number of second subpixels P2 included in the second pixel group PG2 may be designed to be modified according to the resolution of the component area CA.

The component area CA may include the first component area CA1 and the second component area CA2. The plurality of second subpixels P2 may be located in each of the first component area CA1 and the second component area CA2.

A first basic unit U1 including a certain number of second pixel groups PG2 and a certain number of transmission areas TA may be included in the first component area CA1, and a second basic unit U2 including a certain number of second pixel groups PG2 and a certain number of transmission areas TA may be included in the second component area CA2. According to an embodiment, in the first basic unit U1, the second pixel group PG2 may be located on an upper left end of the first basic unit U1. In the second basic unit U2, the second pixel group PG2 may be located on an upper left end of the second basic unit U2.

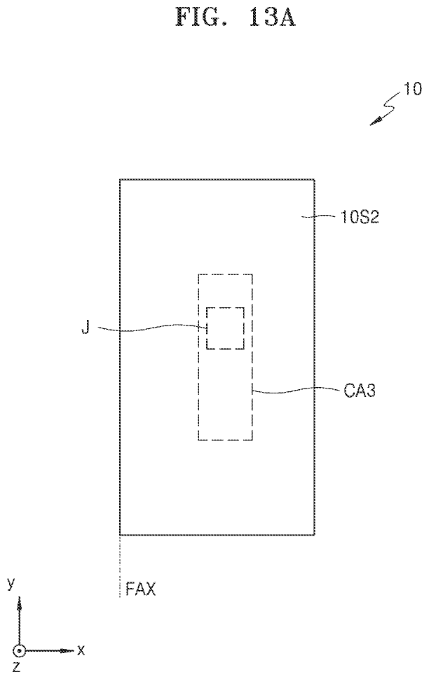

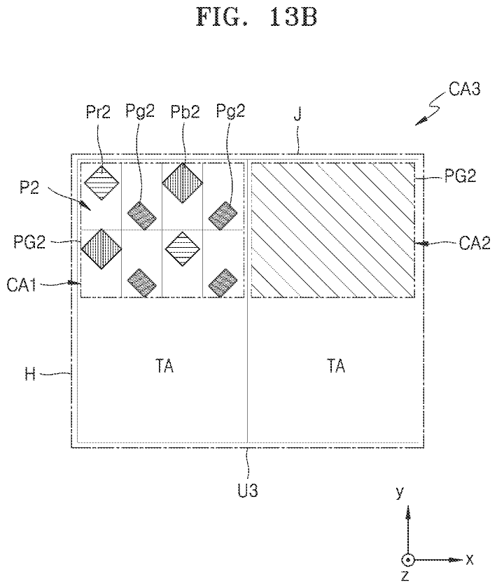

FIG. 13A is a schematic plan view of the display panel 10 of FIG. 12A in a folded state. FIG. 13B is an enlarged view of a portion J of a component area CA of the display panel 10 of FIG. 13A.

Referring to FIGS. 13A and 13B, the display panel 10 may be folded about the folding axis FAX. The display panel 10 may include a second surface 10S2. The second surface 10S2 may be opposite to the first surface 10S1 of FIG. 12A. According to an embodiment, the second surface 10S2 may include a third component area CA3. The third component area CA3 may overlap the first component area CA1 and the second component area CA2 of FIG. 12A. In other words, when the display panel 10 is folded about the folding axis FAX, the first component area CA1 and the second component area CA2 may overlap each other, and each of the first component area CA1 and the second component area CA2 may provide the third component area CA3 which is disposed in the second surface 10S2.

When the display panel 10 is folded about the folding axis FAX, a second pixel group PG2 located in the first component area CA1 and a second pixel group PG2 located in the second component area CA2 may each be located in the third component area CA3. A third basic unit U3 including a certain number of second pixel groups PG2 and a certain number of transmission areas TA may be included in the third component area CA3. In the third component area CA3, the third basic unit U3 may be repeated in an x direction of FIG. 13B and/or a y direction of FIG. 13B. In FIG. 13B, the third basic unit U3 may have a quadrilateral shape in which two second pixel groups PG2 and two transmission areas TA arranged around the two second pixel groups PG2 are grouped.

When the display panel 10 is folded about the folding axis FAX, a second pixel group PG2 of the first component area CA1 may be located on an upper left end of the third basic unit U3. When the display panel 10 is folded about the folding axis FAX, a second pixel group PG2 of the second component area CA2 may be located on an upper right end of the third basic unit U3. When the display panel 10 is folded about the folding axis FAX, a transmission area TA of the first component area CA1 and a transmission area TA of the second component area CA2 may overlap each other. The transmission area TA of the first component area CA1 and the transmission area TA of the second component area CA2 may be located on a lower left end and a lower right end of the third basic unit U3.

When the display panel 10 is folded about the folding axis FAX, a plurality of second subpixels P2 included in the second pixel group PG2 of the first component area CA1 may emit light in a z direction of FIG. 13B in the third component area CA3. When the display panel 10 is folded about the folding axis FAX, a plurality of second subpixels P2 included in the second pixel group PG2 of the second component area CA2 may not emit light in the z direction of FIG. 13B in the third component area CA3. When the display panel 10 is folded about the folding axis FAX, the transmission area TA of the first component area CA1 and the transmission area TA of the second component area CA2 may overlap each other. Accordingly, the display panel 10 may perform an operation of a component or display an image through the third component area CA3.

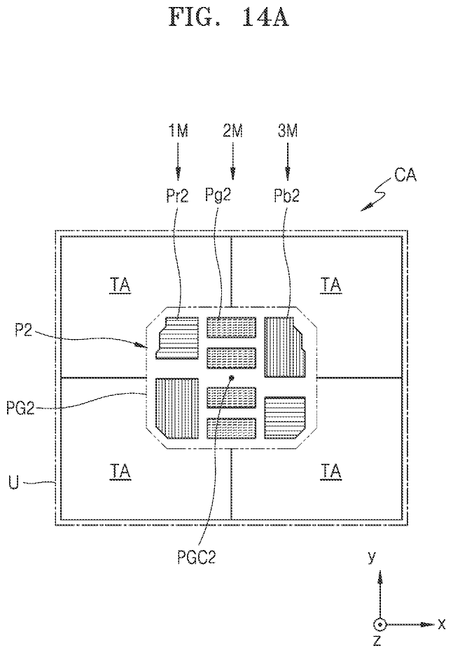

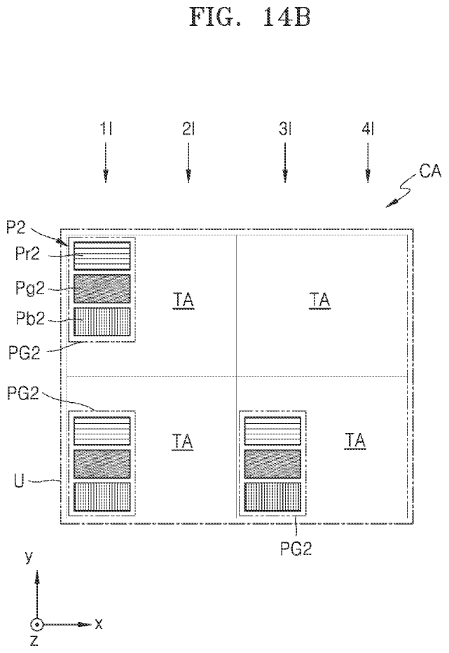

FIGS. 14A and 14B are plan views of a second subpixel P2 arrangement structure of a component area CA, according to various embodiments.

Referring to FIG. 14A, a second pixel group PG2 in a basic unit U may be surrounded by transmission areas TA. A plurality of second subpixels P2 may be located in the second pixel group PG2. According to an embodiment, eight second subpixels P2 may be located in the second pixel group PG2. The second pixel group PG2 may include two second red subpixels Pr2, four second green subpixels Pg2, and two second blue subpixels Pb2.

The eight second subpixels P2 in the second pixel group PG2 may be arranged symmetrically about a center PGG2 of the second pixel group PG2. For example, a second red subpixel Pr2 and a second blue subpixel Pb2 may be located on the first column 1M, and four second green subpixels Pg2 may be located with a predetermined interval between them on the second column 2M. A second blue subpixel Pb2 and a second red subpixels Pr2 may be located on the third column 3M. In this case, the second red subpixel Pr2 located on the first column 1M and the second red subpixel Pr2 located on the third column 3M may be symmetrical about the center PGC2 of the second pixel group PG2. The second blue subpixel Pb2 located on the first column 1M and the second blue subpixel Pb2 located on the third column 3M may be symmetrical about the center PGC2 of the second pixel group PG2. The second green subpixels Pg2 located on the second column 2M may be symmetrical about the center PGC2 of the second pixel group PG2.

According to an embodiment, a length of the second blue subpixel Pb2 in a y direction of FIG. 14A may be greater than that of the second red subpixel Pr2 in the y direction of FIG. 14A. The length of the second blue subpixel Pb2 in the y direction of FIG. 14A may be equal to or greater than a sum of respective lengths of the two second green subpixels Pg2 in the y direction of FIG. 14A.

One of the plurality of second subpixels P2 may have a planar quadrangular shape, and the other of the plurality of second subpixels P2 may have a planar pentagonal shape. For example, each second green subpixel Pg2 may have a planar quadrilateral shape having longer sides and shorter sides, and each second red subpixel Pr2 and/or each second blue subpixel Pb2 may have a planar pentagonal shape. In this case, the second red subpixel Pr2 and/or the second blue subpixel Pb2 may have a side in a direction intersecting an x direction of FIG. 14A or the y direction of FIG. 14A. The side may face a transmission area TA. As another example, some of the plurality of second subpixels P2 may have a planar n-gonal shape having n sides (where n is an integer equal to or greater than 6). In this case, the area of the second pixel group PG2 in the basic unit U may be reduced, and the area of the transmission area TA may be increased, and thus the light transmittance may be improved.

Referring to FIG. 14B, an arrangement structure of the second subpixels P2 of the component area CA may be a stripe structure. The second subpixels P2 included in one second pixel group PG2 may include a second red subpixel Pr2, a second green subpixel Pg2, and a second blue subpixel Pb2. The second red subpixel Pr2, the second green subpixel Pg2, and the second blue subpixel Pb2 may be arranged side by side in the y direction of FIG. 14B. According to an embodiment, the second red subpixel Pr2, the second green subpixel Pg2, and the second blue subpixel Pb2 may have longer sides in the x direction of FIG. 14B.

Alternatively, unlike illustrated, the second red subpixel Pr2, the second green subpixel Pg2, and the second blue subpixel Pb2 may be arranged side by side in the x direction of FIG. 14B. In this case, the second red subpixel Pr2, the second green subpixel Pg2, and the second blue subpixel Pb2 may have longer sides in the y direction of FIG. 14B.

According to an embodiment, two second pixel groups PG2 may be arranged side by side on the first column 11. According to an embodiment, transmission areas TA may be located between the two second pixel groups PG2 on the first column 11. Transmission areas TA may be located on the second column 21 disposed adjacent to the first column 11. Transmission areas TA and one second pixel group PG2 may be located on the third column 31 disposed adjacent to the second column 21. Transmission areas TA may be located on the fourth column 41 disposed adjacent to the third column 31. In other words, the second pixel groups PG2 may be located on an upper left side, a lower left side, and a lower right side of the basic unit U.

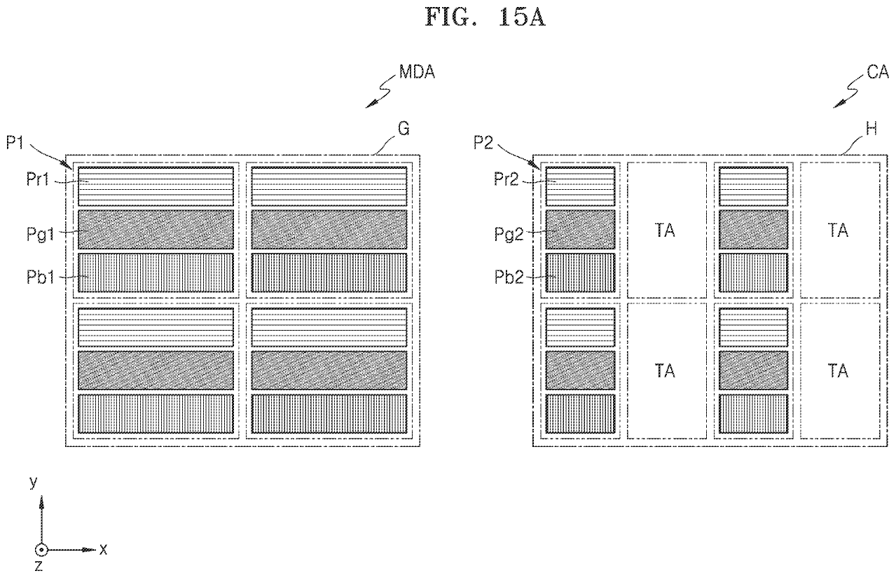

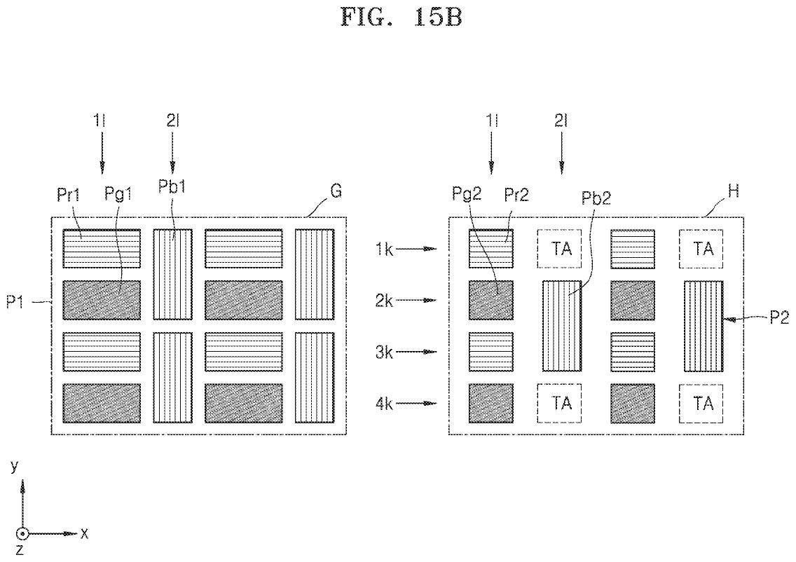

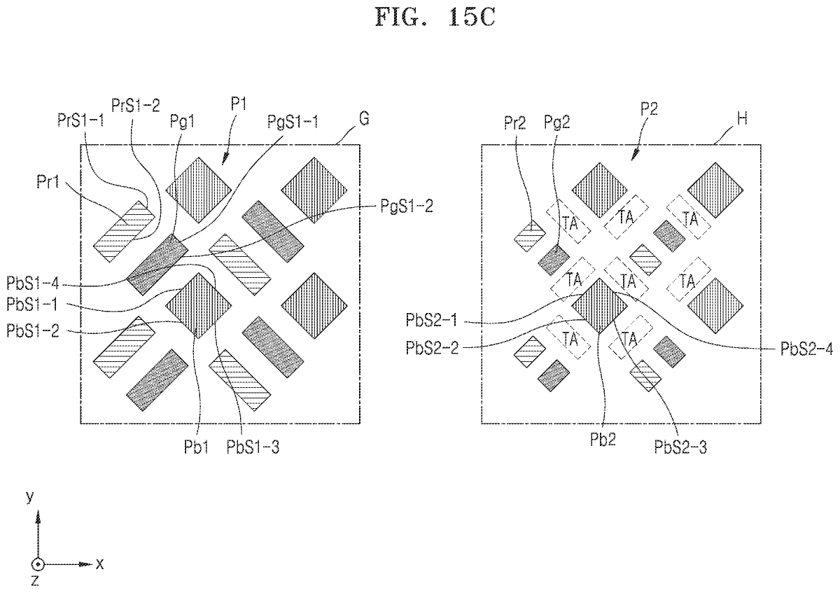

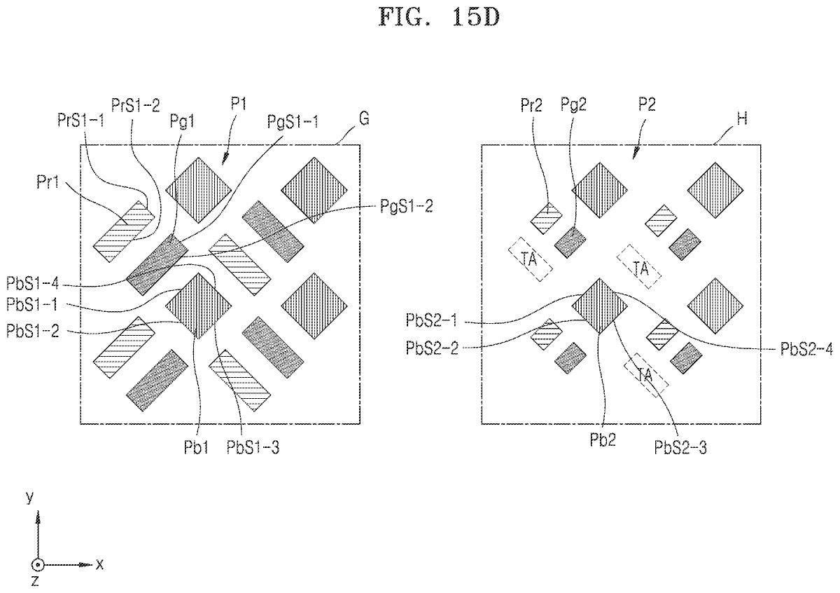

FIGS. 15A, 15B, 15C, and 15D are enlarged views of a portion G of the display panel 10 of FIG. 12A and a portion H of the display panel 10 of FIG. 12A, according to various embodiments.

Referring to FIGS. 15A, 15B, 15C, and 15D, the display panel 10 may include a plurality of first subpixels P1 located in the main display area MDA and a plurality of second subpixels P2 located in the component area CA. According to an embodiment, the plurality of first subpixels P1 may include a first subpixel P1, and the plurality of second subpixels P2 may include a second subpixel P2 emitting light of the same color as the first subpixel P1. In this case, a planar area of the first subpixel P1 may be greater than that of the second subpixel P2.

According to an embodiment, the plurality of first subpixels P1 may include a first red subpixel Pr1, a first green subpixel Pg1 and a first blue subpixel Pb1 The plurality of second subpixels P2 may include a second red subpixel Pr2, a second green subpixel Pg2, and a second blue subpixel Pb2. In this case, the first red subpixel Pr1 and the second red subpixel Pr2 may emit light of the same red color, and the planar area of the first red subpixel Pr1 may be greater than that of the second red subpixel Pr2. The first green subpixel Pg1 and the second green subpixel Pg2 may emit light of the same green color, and the planar area of the first green subpixel Pg1 may be greater than that of the second green subpixel Pg2. The first blue subpixel Pb1 and the second blue subpixel Pb2 may emit light of the same blue color, and the planar area of the first blue subpixel Pb1 may be greater than that of the second blue subpixel Pb2. Transmission areas TA may be located in the component area CA. According to an embodiment, a percentage of the area of wires within a display apparatus when the display apparatus is a tablet PC may be less than a percentage of the area of wires within the display apparatus when the display apparatus is a smartphone. Accordingly, resolution in the main display area MDA may be equal to resolution in the component area CA.

Referring to FIG. 15A, the plurality of first subpixels P1 and the plurality of second subpixels P2 may be arranged in a stripe structure. The first red subpixel Pr1, the first green subpixel Pg1, and the first blue subpixel Pb1 may be arranged side by side in the y direction of FIG. 15A. The second red subpixel Pr2, the second green subpixel Pg2, and the second blue subpixel Pb2 may be arranged side by side in the y direction of FIG. 15A.

Referring to FIG. 15B, the plurality of first subpixels P1 and the plurality of second subpixels P2 may be arranged in an S-stripe structure. A first red subpixel Pr1 and a first green subpixel Pg1 may alternate with each other on the first column 11, and first blue subpixels P111 may be located with a predetermined interval between them on the second column 21 disposed adjacent to the first column 11.

In the component area CA, a second red subpixel Pr2 and a transmission area TA may be arranged alternately on a first row 1k. A second green subpixel Pg2 and a second blue subpixel Pb2 may be arranged alternately on a second row 2k adjacent to the first row 1k. Second red subpixels Pr2 may be located with a predetermined interval between them on a third row 3k disposed adjacent to the second row 2k. In this case, the second blue subpixel Pb2 may extend from the second row 2k to the third row 3k. Accordingly, the second blue subpixel Pb2 may be located between the plurality of second red subpixels Pr2 on the third row 3k. A second green subpixel Pg2 and a transmission area TA may be arranged alternately on a fourth row 4k adjacent to the third row 3k.

Referring to FIG. 15C, a plurality of first blue subpixels Pb1 may be included in the portion G of the display panel. The plurality of first blue subpixels P111 may be spaced apart at regular intervals in an x direction and/or y direction of FIG. 15C. According to an embodiment, each first blue subpixel Pb1 may be arranged in a diamond shape. The first blue subpixel Pb1 may have a first upper left edge PbS1-1, a first lower left edge PbS1-2, a first lower right edge PbS1-3, and a first upper right edge PbS1-4.

Each first green subpixel Pg1 may have a first green subpixel shorter edge PgS1-1 and a first green subpixel longer edge PgS1-2. A first green subpixel Pg1 may be located on one side of the first blue subpixel Pb1. According to an embodiment, four first green subpixels Pg1 may be located on sides of the first blue subpixel Pb1, respectively.

Each first red subpixel Pr1 may have a first red subpixel shorter edge PrS1-1 and a first red subpixel longer edge PrS1-2. A first red subpixel Pr1 may be located on one side of the first blue subpixel Pb1. According to an embodiment, four first red subpixels Pr1 may be located on sides of the first blue subpixel Pb1, respectively.

A first red subpixel Pr1 located on one side of the first upper left edge PbS1-1 may be arranged so that the first red subpixel longer edge PrS1-2 extends in the same direction as the first upper left edge PbS1-1. In this case, a first green subpixel Pg1 located on one side of the first left upper edge PbS1-1 may be disposed between the first blue subpixel P111 and the first red subpixel Pr1 located on one side of the first upper left edge PbS1-1, and the first green subpixel longer edge PgS1-2 may extend in the same direction as the first upper left edge PbS1-1.

A first red subpixel Pr1 located on one side of the first lower left edge PbS1-2 may be arranged so that the first red subpixel shorter edge PrS1-1 extends in the same direction as the first lower left edge PbS1-2. In this case, a first green subpixel Pg1 located on one side of the first lower left edge PbS1-2 may be arranged so that the first green subpixel shorter edge PgS1-1 extends in the same direction as the first lower left edge PbS1-2. In this case, the first red subpixel Pr1 located on one side of the first lower left edge PbS1-2 and the first green subpixel Pg1 located on one side of the first lower left edge PbS1-2 may be arranged side by side.

A first red subpixel Pr1 located on one side of the first lower right edge PbS1-3 may be arranged so that the first red subpixel shorter edge PrS1-1 extends in the same direction as the first lower right edge PbS1-3. In this case, a first green subpixel Pg1 located on one side of the first lower right edge PbS1-3 may be arranged so that the first green subpixel shorter edge PgS1-1 extends in the same direction as the first lower right edge PbS1-3. In this case, the first red subpixel Pr1 located on one side of the first lower right edge PbS1-3 and the first green subpixel Pg1 located on one side of the first lower right edge PbS1-3 may be arranged side by side.

According to an embodiment, the first green subpixel Pg1 located on one side of the first lower left edge PbS1-2 and the first red subpixel Pr1 located on one side of the first lower right edge PbS1-3 may be disposed adjacent to each other.

A first green subpixel Pg1 located on one side of the first upper right edge PbS1-4 may be arranged so that the first green subpixel longer edge PgS1-2 extends in the same direction as the first upper right edge PbS1-4. In this case, a first red subpixel Pr1 located on one side of the first upper right edge PbS1-4 may be disposed between the first blue subpixel Pb1 and the first green subpixel Pg1 located on one side of the first upper right edge PbS1-4, and the first red subpixel longer edge PrS1-2 may extend in the same direction as the first upper right edge PbS1-4.

The first green subpixel Pg1 located on one side of the first upper left edge PbS1-1 and the first red subpixel Pr1 located on one side of the first upper right edge PbS1-4 may be disposed adjacent to each other. Each of the first green subpixel Pg1 located on one side of the first upper left edge PbS1-1 and the first red subpixel Pr1 located on one side of the first upper right edge PbS1-4 may surround at least a portion of the first blue subpixel Pb1.

A plurality of second blue subpixels Pb2 may be included in the portion H of the display panel. The plurality of second blue subpixels Pb2 may be spaced apart at regular intervals in the x direction and/or y direction of FIG. 15C. According to an embodiment, each second blue subpixel Pb2 may be arranged in a diamond shape. The second blue subpixel Pb2 may have a second left upper edge PbS2-1, a second left lower edge PbS2-2, a second right lower edge PbS2-3, and a second right upper edge PbS2-4.

According to an embodiment, four second green subpixels Pg2 may be located on sides of the second blue subpixel Pb2, respectively. According to an embodiment, four second red subpixels Pr2 may be located on sides of the second blue subpixel Pb2, respectively.

A second green subpixel Pg2 located on one side of the second upper left edge PbS2-1 of the second blue subpixel Pb2 may be disposed between a second red subpixel Pr2 located on one side of the second upper left edge PbS2-1 and the second blue subpixel Pb2. A second red subpixel Pr2 located on one side of the second upper right edge PbS2-4 of the second blue subpixel Pb2 may be disposed between a second green subpixel Pg2 located on one side of the second upper right edge PbS2-4 and the second blue subpixel Pb2. The second green subpixel Pg2 located on one side of the second upper left edge PbS2-1 of the second blue subpixel Pb2 and the second red subpixel Pr2 located on one side of the second upper right edge PbS2-4 may be disposed adjacent to each other.

A second red subpixel Pr2 located on one side of the second lower left edge PbS2-2 of the second blue subpixel Pb2 and a second green subpixel Pg2 located on one side of the second lower left edge PbS2-2 of the second blue subpixel Pb2 may be arranged side by side. A second red subpixel Pr2 located on one side of the second lower right edge PbS2-3 of the second blue subpixel Pb2 and a second green subpixel Pg2 located on one side of the second lower right edge PbS2-3 of the second blue subpixel Pb2 may be arranged side by side. According to an embodiment, the second green subpixel Pg2 located on one side of the second lower left edge PbS2-2 of the second blue subpixel Pb2 and the second red subpixel Pr2 located on one side of the second lower right edge PbS2-3 may be disposed adjacent to each other.

Referring to FIG. 15D, a plurality of second blue subpixels Pb2 may be included in the portion H of the display panel. The plurality of second blue subpixels Pb2 may be spaced apart at regular intervals in the x direction and/or y direction of FIG. 15D. According to an embodiment, each second blue subpixel Pb2 may be arranged in a diamond shape. The second blue subpixel Pb2 may have a second upper left edge PbS2-1, a second lower left edge PbS2-2, a second lower right edge PbS2-3, and a second upper right edge PbS2-4.

A second red subpixel Pr2 located on one side of the second lower left edge PbS2-2 and a second green subpixel Pg2 located on one side of the second lower left edge PbS2-2 may be arranged side by side.

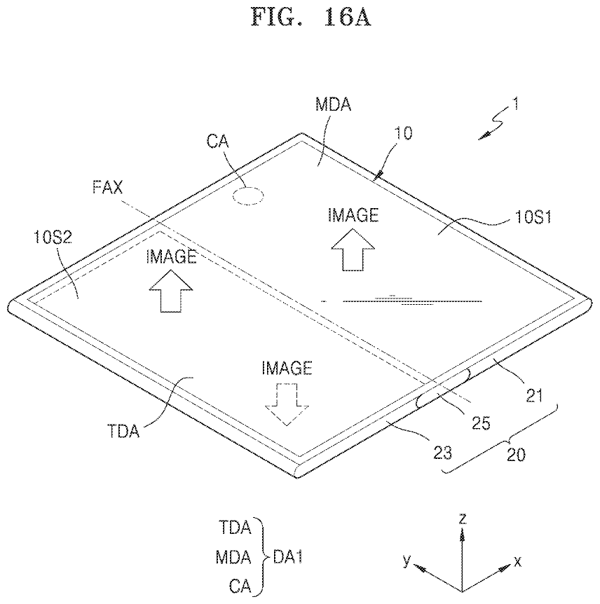

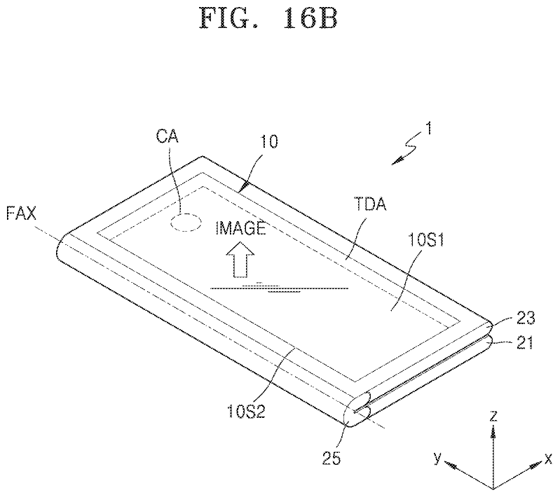

FIG. 16A is a schematic perspective view of a display apparatus 1 according to another embodiment in an unfolded state. FIG. 16B is a schematic perspective view of the display apparatus 1 according to another embodiment in a folded state. Reference numerals in FIGS. 16A and 16B that are the same as the reference numerals in FIGS. 1A and 1B denote the same elements, and thus repeated descriptions thereof are omitted.

Referring to FIGS. 16A and 16B, the display apparatus 1 may be folded. According to an embodiment, the display apparatus 1 may be folded about a folding axis FAX. The display apparatus 1 may include a display panel 10 and a case 20, and the display panel 10 may include a first surface 10S1 and a second surface 10S2. The second surface 10S2 may be a surface opposite to the first surface 10S1. The first surface 10S1 may include a first display area DA1.

The first display area DA1 may include a main display area MDA, a component area CA, and a transparent display area TDA. The main display area MDA may surround at least a portion of the component area CA. The transparent display area TDA may be located on one side of the main display area MDA with the folding axis FAX extending across the first surface 10S1 disposed between the transparent display area TDA and the main display area MDA. Light transmittance of the transparent display area TDA may be higher than light transmittance of the main display area MDA. The transparent display area TDA may display an image even on the second surface 10S2 of the display panel 10. Accordingly, the display panel 10 may display an image on the first surface 10S1 and may display an image on the second surface 10S2.

The case 20 may protect the display panel 10. The case 20 may house the display panel 10. The case 20 may include a first portion 21, a second portion 23, and a third portion 25 that protect the display panel 10. The first portion 21 may overlap the main display area MDA and the component area CA. The second portion 23 may overlap the transparent display area TDA. The second portion 23 may expose the transparent display area TDA. For example, a portion of the second portion 23 that overlaps the transparent display area TDA in a plan view may be transparent. As another example, the second portion 23 may include an opening that exposes the transparent display area TDA. The third portion 25 may be disposed between the first portion 21 and the second portion 23.

The case 20 may be folded about the folding axis FAX disposed between the first portion 21 and the second portion 23. According to an embodiment, the third portion 25 may have a hinge structure.

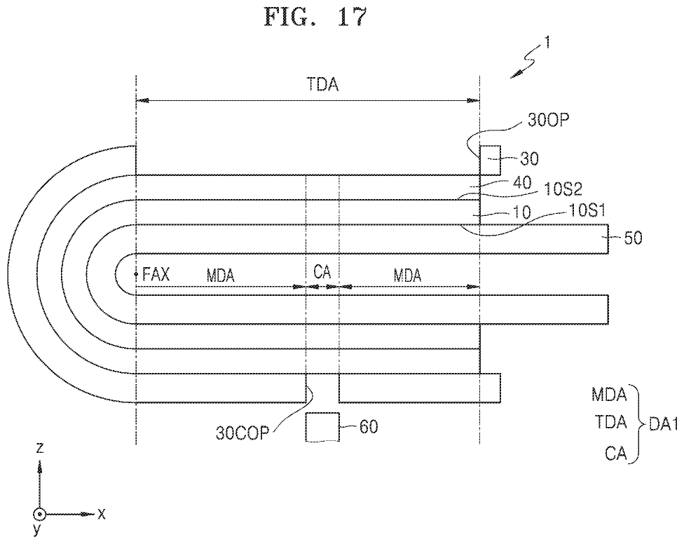

FIG. 17 is a schematic cross-sectional view of the display apparatus 1 according to another embodiment. Reference numerals in FIG. 17 that are the same as the reference numerals in FIG. 11 denote the same elements, and thus repeated descriptions thereof are omitted.

Referring to FIG. 17, the display apparatus 1 may include a display panel 10, a set assembly 30, a cover panel 40, a cover window 50, and a component 60. The display panel 10 may display an image. According to an embodiment, the display panel 10 may include a first surface 10S1 and a second surface 10S2. The first surface 10S1 and the second surface 10S2 may be opposite to each other. The first surface 1051 may include a first display area DA1 displaying an image. The first display area DA1 may include a main display area MDA, a component area CA, and a transparent display area TDA.

The display apparatus 1 may be folded about the folding axis FAX extending across the first surface 10S1. The main display area MDA and the component area CA of the display panel 10 folded about the folding axis FAX may face the transparent display area TDA of the display panel 10. According to another embodiment, the main display area MDA and the component area CA of the display panel 10 folded about the folding axis FAX may face the transparent display area TDA of the display panel 10.

The set assembly 30 may be located on the second surface 1052. The set assembly 30 may support the display panel 10. The set assembly 30 may include an opening 30OP exposing the second surface 1052. The opening 30OP may expose the transparent display area TDA. According to an embodiment, the opening 30OP may entirely expose the transparent display area TDA. According to an embodiment, the set assembly 30 may include a component opening 30COP formed in an area corresponding to the component 60.

The cover panel 40 may be disposed between the display panel 10 and the set assembly 30. According to an embodiment, the cover panel 40 may continuously extend on the second surface 10S2. Accordingly, even when the set assembly 30 includes the opening 30OP and the component opening 30COP, the cover panel 40 may protect the display panel 10.

The component 60 may overlap the component area CA. The component 60 may be located to overlap the first component area CAL According to an embodiment, when the display apparatus 1 is folded about the folding axis FAX, the component 60 may overlap the component area CA and the transparent display area TDA. According to an embodiment, when the display apparatus 1 is unfolded, the component 60 may overlap the component area CA and may not overlap the transparent display area TDA.

According to an embodiment, when the display apparatus 1 is folded about the folding axis FAX, the component area CA and the opening 30OP may overlap each other. According to an embodiment, when the display apparatus 1 is folded about the folding axis FAX, the component area CA and the transparent display area TDA may overlap each other. According to an embodiment, when the display apparatus 1 is folded about the folding axis FAX, the component opening 30COP and the opening 30OP may overlap each other. Accordingly, when the display apparatus 1 is folded about the folding axis FAX, the display apparatus 1 may perform an operation of the component 60 via the opening 30OP or may display an image. According to an embodiment, when the display apparatus 1 is unfolded, the component opening 30COP and the opening 30OP may not overlap each other.

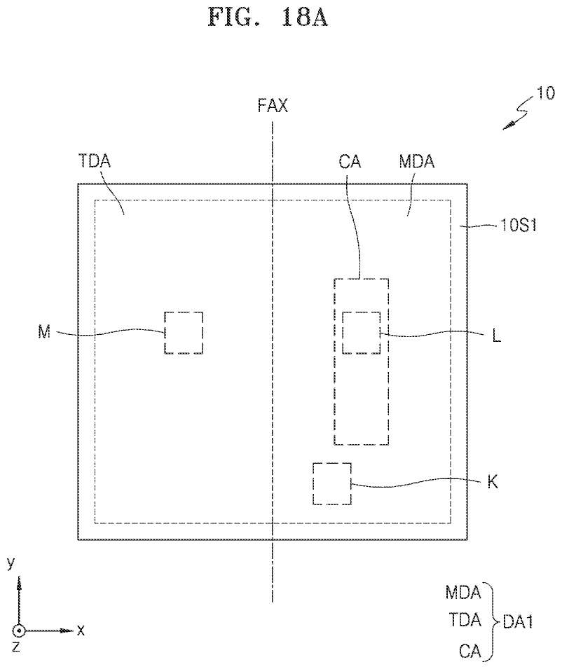

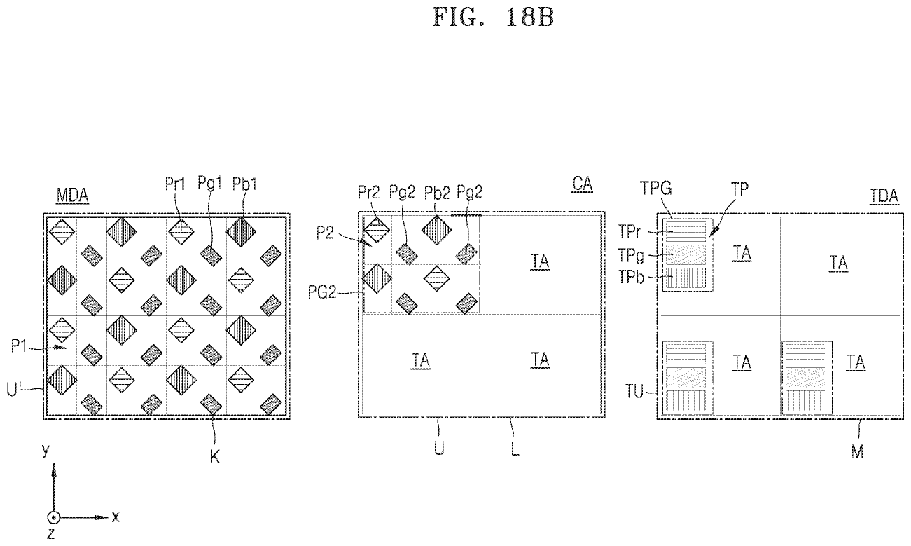

FIG. 18A is a schematic plan view of the display panel 10 included in the display apparatus 1 of FIG. 17. FIG. 18B is an enlarged view of a portion K of the main display area MDA of the display panel 10 of FIG. 18A, a portion L of the component area CA of the display panel 10 of FIG. 18A, and a portion M of the transparent display area TDA of the display panel 10 of FIG. 18A.

Referring to FIGS. 18A and 18B, the display panel 10 may include the first surface 10S1 including the first display area DA1. The first display area DA1 may include the main display area MDA, the component area CA, and the transparent display area TDA. The main display area MDA may surround at least a portion of the component area CA. According to an embodiment, the main display area MDA may entirely surround the component area CA.

The display panel 10 may be folded about the folding axis FAX extending across the first surface 10S1. According to an embodiment, the transparent display area TDA may be located on one side of the main display area MDA with the folding axis FAX disposed between the transparent display area TDA and the main display area MDA. The component area CA and the transparent display area TDA may be spaced apart from each other with the folding axis FAX disposed therebetween.

The display panel 10 may include a plurality of first subpixels P1 located in the main display area MDA. According to an embodiment, the plurality of first subpixels P1 may include a first red subpixel Pr1, a first green subpixel Pg1, and a first blue subpixel Pb1. The plurality of first subpixels P1 may be arranged in a PENTILE™ matrix structure.

According to an embodiment, each first subpixel P1 may include an organic light-emitting diode. The organic light-emitting diode may include a pixel electrode, an emission layer, and an opposite electrode. According to an embodiment, the pixel electrode may include a plurality of layers. According to an embodiment, the pixel electrode may include a first layer, a second layer, and a third layer. The first layer may include transparent conductive oxide. The second layer may include a reflection film. The third layer may include transparent conductive oxide. In this case, the first subpixel P1 may emit light in a z direction of FIG. 18B so that the first display area DA1 of the display panel 10 displays an image.

The display panel 10 may include a plurality of second subpixels P2 located in the component area CA. According to an embodiment, the plurality of second subpixels P2 may include a second red subpixel Pr2, a second green subpixel Pg2, and a second blue subpixel Pb2. According to an embodiment, the plurality of second subpixels P2 may be arranged in a ¼ PenTile structure.

The component area CA may include a transmission area TA disposed adjacent to the second pixel group PG2 which includes a plurality of second subpixels P2. The second pixel group PG2 and the transmission area TA may be adjacent to each other in an x direction of FIG. 18B and/or a y direction of FIG. 18B.

The display panel 10 may include a plurality of transparent subpixels TP located in the transparent display area TDA. According to an embodiment, the plurality of transparent subpixels TP may include a red transparent subpixel TPr, a green transparent subpixel TPg, and a blue transparent subpixel TPb.

The transparent display area TDA may include a transmission area TA disposed adjacent to the plurality of transparent subpixels TP. The plurality of transparent subpixels TP and the transmission area TA may be disposed adjacent to each other in the x direction of FIG. 18B and/or the y direction of FIG. 18B.

The plurality of transparent subpixels TP may constitute a transparent pixel group TPG. In other words, the transparent pixel group TPG may be defined as a subpixel set in which a plurality of transparent subpixels TP are grouped in a predetermined unit. In FIG. 18B, one transparent pixel group TPG may include one red transparent subpixel TPr, one green transparent subpixel TPg, and one blue transparent subpixel TPb.

A transparent basic unit TU including a certain number of transparent pixel groups TPG and a certain number of transmission areas TA may be included in the transparent display area TDA. In the transparent display area TDA, the transparent basic unit TU may be repeated in the x direction of FIG. 18B and/or the y direction of FIG. 18B.

According to an embodiment, because an arrangement of transparent pixel groups TPG and transmission areas TA in the transparent basic unit TU is similar to that of second pixel groups PG2 and transmission areas TA in the basic unit U of FIG. 14B, a detailed description thereof will be omitted.

According to an embodiment, each transparent subpixel TP may include a transparent organic light-emitting diode as a display element. The transparent organic light-emitting diode may include a transparent pixel electrode, an emission layer, and an opposite electrode. In this case, the transparent pixel electrode may include transparent conductive oxide. According to an embodiment, the transparent pixel electrode may include at least one of indium (In), tin (Sn), and oxygen (O). According to an embodiment, the transparent pixel electrode may include conductive oxide such as indium tin oxide (ITO), indium zinc oxide (IZO), zinc oxide (ZnO), indium oxide (In₂O₃), indium gallium oxide (IGO), or aluminum zinc oxide (AZO). Accordingly, the transparent subpixel TP may emit light in a z direction of FIG. 18B so that the first display area DA1 of the display panel 10 displays an image. The transparent pixel electrode may include no reflective films. Accordingly, the transparent subpixel TP may emit light in a −z direction of FIG. 18B so that the second surface 10S2 of the display panel 10 displays an image. Light transmittance of the transparent display area TDA may be higher than light transmittance of the main display area MDA.

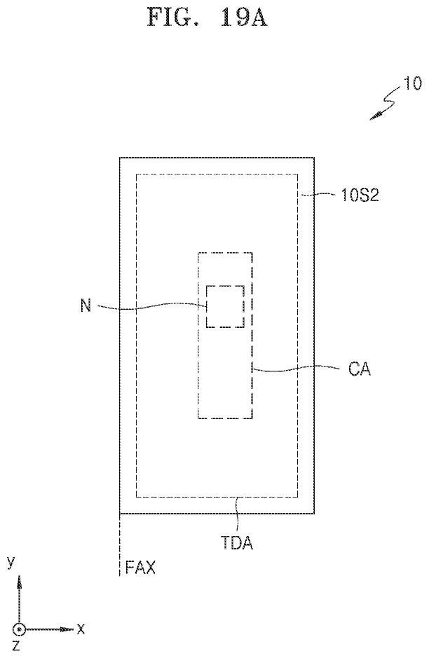

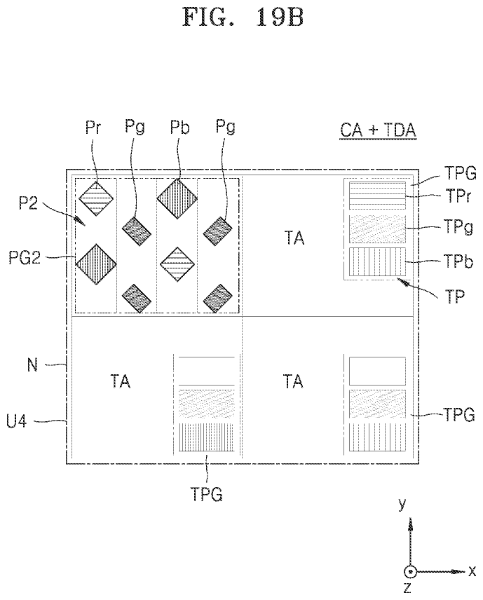

FIG. 19A is a schematic plan view of the display panel 10 of FIG. 18A in a folded state. FIG. 19B is an enlarged view of a portion N of a second surface 10S of the display panel 10 of FIG. 19A.

Referring to FIGS. 19A and 19B, the display panel 10 may be folded about the folding axis FAX. The display panel 10 may include the second surface 10S2. The second surface 10S2 may be opposite to a first surface 10S1 of FIG. 18A. According to an embodiment, the second surface 10S2 of the display panel 10 may display an image. In other words, because the transparent display area TDA of the first surface 10S1 of the display panel 10 has relatively high light transmittance, the display panel 10 may display an image even through the second surface 10S2 of the display panel 10.

When the display panel 10 is folded about the folding axis FAX, a second pixel group PG2 located in the component area CA and a transparent pixel group TPG located in the transparent display area TDA may be arranged on the second surface 10S2 of the display panel 10 in a plan view. A fourth basic unit U4 including a certain number of second pixel groups PG2, a certain number of transparent pixel groups TPG, and a certain number of transmission areas TA may be included in the second surface 10S2 of the display panel 10 in a plan view. In the second surface 10S2 of the display panel 10, the fourth basic unit U4 may be repeated in an x direction of FIG. 19B and/or a y direction of FIG. 19B. In FIG. 19B, the fourth basic unit U4 may have a quadrilateral shape in which one second pixel group PG2, three transparent pixel groups TPG, and three transmission areas TA are grouped.

When the display panel 10 is folded about the folding axis FAX, the second pixel group PG2 of the component area CA may be located on an upper left end of the fourth basic unit U4. When the display panel 10 is folded about the folding axis FAX, transparent pixel groups TPG and transmission areas TA of the transparent display area TDA may be located on an upper right end of the fourth basic unit U4, a lower left end of the fourth basic unit U4, and a lower right end of the fourth basic unit U4.

When the display panel 10 is folded about the folding axis FAX, a plurality of second subpixels P2 included in the second pixel group PG2 of the component area CA may emit light in a z direction of FIG. 19B. When the display panel 10 is folded about the folding axis FAX, a plurality of transparent subpixels TP included in the transparent pixel group TPG located in the transparent display area TDA may emit light in the z direction of FIG. 19B and/or a −z direction of FIG. 19B. When the display panel 10 is folded about the folding axis FAX, the transmission areas TA of the component area CA and the transmission areas TA of the transparent display area TDA may overlap each other. Accordingly, the display panel 10 may perform an operation of a component or display an image through the second surface 10S2.

As described above, a display panel according to an embodiment may include a plurality of first thin-film transistors in a first pixel circuit, the number of the plurality of first thin-film transistors in the first pixel circuit is greater than the number of second thin-film transistor included in a second pixel circuit, and may have a first surface including a first display area and a second surface opposite to the first surface and including a second display area. Accordingly, the display panel may display an image through the first surface and the second surface.

A display apparatus according to an embodiment may include a display panel including a first surface including a first display area and a second surface opposite to the first surface and including a second display area, and a set assembly located on the second surface and including an opening exposing the second display area. Accordingly, the display apparatus may display an image through the first surface and the second surface.

In addition, when the display apparatus according to an embodiment is folded about a folding axis extending across the first surface of the display panel, a component area may overlap the opening. Accordingly, when the display apparatus is folded about the folding axis, the display apparatus may perform an operation of a component or display an image through the opening.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

1. A display panel comprising:
a substrate;
a pixel circuit layer disposed on the substrate and comprising a first pixel circuit which includes a plurality of first thin-film transistors and a second pixel circuit which includes a plurality of second thin-film transistors; and
a display element layer disposed on the pixel circuit layer and comprising a first display element connected to the first pixel circuit and a second display element connected to the second pixel circuit,
wherein a number of the plurality of first thin-film transistors in the first pixel circuit is greater than a number of the plurality of second thin-film transistors in the second pixel circuit, and
wherein the display panel has a first surface including a first display area and a second surface opposite to the first surface and including a second display area.

2. The display panel of claim 1, wherein the substrate comprises a first area and a second area disposed adjacent to the first area, the first pixel circuit and the second pixel circuit overlap the first area, the first display element overlaps the first area, and the second display element overlaps the second area.

3. The display panel of claim 2, wherein the pixel circuit layer further comprises a connection line extending from the first area to the second area and connecting the second pixel circuit to the second display element, and
wherein the connection line comprises transparent conductive oxide.

4. The display panel of claim 1, wherein the first display element including a first pixel electrode which has a first thickness and comprises a plurality of layers, and the second display element including a second pixel electrode which has a second thickness less than the first thickness and comprises a transparent conductive oxide.

5. The display panel of claim 1, wherein the pixel circuit layer further comprises:
a first semiconductor layer disposed on the substrate and constituting the plurality of first thin-film transistors;
a first insulating layer covering the first semiconductor layer;
a second semiconductor layer disposed on the first insulating layer and constituting the plurality of second thin-film transistors; and
a second insulating layer covering the second semiconductor layer.

6. The display panel of claim 1, further comprising:
a first reflective layer disposed between the pixel circuit layer and the first display element to overlap the first display element in a plan view; and
a second reflective layer disposed on the display element layer to overlap the second display element in a plan view.

7. The display panel of claim 1, wherein the pixel circuit layer further comprises:
a scan line connected to each of the first pixel circuit and the second pixel circuit;
a first data line connected to the first pixel circuit; and
a second data line connected to the second pixel circuit and disposed on a different layer from a layer on which the first data line is disposed.

8. A display apparatus comprising:
a display panel that has a first surface including a first display area and has a second surface opposite to the first surface and including a second display area; and
a set assembly disposed on the second surface and comprising an opening exposing the second display area.

9. The display apparatus of claim 8, further comprising a cover panel disposed between the display panel and the set assembly,
wherein the cover panel continuously extends on the second surface of the display panel to cover the opening.

10. The display apparatus of claim 8, wherein the display panel comprises:
a substrate;
a pixel circuit layer disposed on the substrate and comprising a first pixel circuit which includes a plurality of first thin-film transistors and a second pixel circuit which includes a plurality of second thin-film transistors; and
a display element layer disposed on the pixel circuit layer and comprising a first display element connected to the first pixel circuit and a second display element connected to the second pixel circuit, and
wherein a number of the plurality of first thin-film transistors in the first pixel circuit is greater than a number of the plurality of second thin-film transistors in the second pixel circuit.

11. The display apparatus of claim 10, wherein the substrate comprises a first area and a second area disposed adjacent to the first area, the first pixel circuit and the second pixel circuit overlap the first area, the first display element overlaps the first area, and the second display element overlaps the second area.

12. The display apparatus of claim 11, wherein the pixel circuit layer further comprises a connection line extending from the first area to the second area and connecting the second pixel circuit to the second display element, and
wherein the connection line comprises transparent conductive oxide.

13. The display apparatus of claim 10, wherein the first display element including a first pixel electrode which has a first thickness and comprises a plurality of layers, and the second display element including a second pixel electrode which has a second thickness less than the first thickness and comprises a transparent conductive oxide.

14. The display apparatus of claim 10, wherein the display panel further comprises:
a first reflective layer disposed between the pixel circuit layer and the first display element to overlap the first display element in a plan view; and
a second reflective layer disposed on the display element layer to overlap the second display element in a plan view.

15. The display apparatus of claim 8, wherein the display apparatus is a foldable display which has a folding axis extending across the first surface.

16. A display apparatus comprising:
a display panel that has a first surface including a first display area and a second surface opposite to the first surface; and
a set assembly disposed on the second surface and comprising an opening exposing the second surface,
wherein the first display area comprises a component area and a main display area surrounding at least a portion of the component area,
wherein the display panel comprises a plurality of first subpixels disposed in the main display area and a plurality of second subpixels, disposed in the component area,
wherein the component area comprises a transmission area disposed adjacent to the plurality of second subpixels, and
wherein, when the display apparatus is folded about a folding axis extending across the first surface, the component area and the opening overlap each other.

17. The display apparatus of claim 16, wherein the component area comprises a first component area and a second component area arranged with the folding axis disposed between the first component area and the second component area, and
wherein, when the display apparatus is folded about the folding axis, the first component area and the second component area overlap each other.

18. The display apparatus of claim 16, wherein the first display area further comprises a transparent display area disposed on one side of the main display area with the folding axis interposed between the main display area and the transparent display area and having greater light transmittance than light transmittance of the main display area, and,
wherein, when the display apparatus is folded about the folding axis, the component area and the transparent display area overlap each other.

19. The display apparatus of claim 16, wherein the plurality of first subpixels comprise a first subpixel emitting a first color of light, and the plurality of second subpixels comprise a second subpixel emitting the first color of light, and
wherein a planar area of the first subpixel is greater than a planar area of the second subpixel.

20. The display apparatus of claim 16, further comprising a component overlapping the component area.
